(19) United States
(12) Patent Application Publication
(10) Pub. No.: US 2025/0380588 A1
(43) Pub. Date: Dec. 11, 2025

(54) DISPLAY PANEL AND ELECTRONIC DEVICE

(71) Applicant: Samsung Display Co., LTD., Yongin-si (KR)

(72) Inventors: Sunkwun Son, Yongin-si (KR); Yongwoo Lee, Yongin-si (KR); Cheolgon Lee, Yongin-si (KR)

(21) Appl. No.: 19/233,185

(22) Filed: Jun. 10, 2025

(30) Foreign Application Priority Data
Jun. 11, 2024 (KR) 10-2024-0075818

(51) Int. Cl. H10K 59/131

(52) U.S. Cl. CPC H10K 59/131

(57) ABSTRACT

A display panel includes first and second semiconductor patterns extending in a first direction, a first conductive pattern including a portion overlapping the first semiconductor pattern, a second conductive pattern including a line portion extending in a second direction and branch portions extending in the first direction and each overlapping the first conductive pattern, first and second conductive lines extending in the second direction, third and fourth conductive lines extending in the second direction, and overlapping the first and second conductive lines, respectively, a third conductive pattern including a first portion overlapping the third conductive line and a second portion overlapping the fourth conductive line, a fifth conductive line extending in the first direction, and including a portion overlapping the third conductive pattern, and sixth and seventh conductive lines extending in the second direction and electrically connected to the first semiconductor pattern and the second conductive pattern, respectively.

This application claims priority to Korean Patent Application No. 10-2024-0075818, filed on Jun. 11, 2024, and all the benefits accruing therefrom under 35 U.S.C. § 119, the content of which in its entirety is herein incorporated by reference.

### BACKGROUND

### 1. Field

One or more embodiments relate to a structure of a display panel.

### 2. Description of the Related Art

Mobility-based electronic devices are widely used. In addition to portable electronic devices such as, for example, mobile phones, recent developments in mobile electronics include electronic devices such as, for example, head-mounted displays (HMDs) that users may wear on the head to experience augmented reality (AR) or virtual reality (VR).

Such electronic devices include display panels to provide users with various functions, for example, visual information such as, for example, still images or moving images. As components for driving display panels decrease in size, the importance of the display panels in electronic devices is steadily increasing.

### SUMMARY

One or more embodiments provide a display panel with improved resolution and display quality. However, this is an example, and the scope of embodiments of the present disclosure are not limited thereto.

Additional aspects will be set forth in part in the description which follows and, in part, will be apparent from the description, or may be learned by practice of the presented embodiments of the disclosure.

According to one or more embodiments, a display panel includes a substrate, a first semiconductor pattern disposed on the substrate and extending in a first direction, a first conductive pattern disposed on the first semiconductor pattern and including a portion overlapping the first semiconductor pattern, a second conductive pattern disposed on the first conductive pattern and including a line portion extending in a second direction, which is perpendicular to the first direction, and branch portions extending from the line portion in the first direction and each overlapping the first semiconductor pattern and the first conductive pattern, a first conductive line and a second conductive line respectively disposed on the second conductive pattern and extending in the second direction, a second semiconductor pattern disposed on the first conductive line and the second conductive line and extending in the first direction, a third conductive line disposed on the second semiconductor pattern, extending in the second direction, and overlapping the first conductive line, a fourth conductive line disposed on the second semiconductor pattern, extending in the second direction, and overlapping the second conductive line, a third conductive pattern disposed on the third conductive line and the fourth conductive line and including a first portion overlapping the third conductive line, a second portion overlapping the fourth conductive line, and a third portion located between the first portion and the second portion, a fifth conductive line disposed on the third conductive pattern, extending in the first direction, and including a portion overlapping the third conductive pattern, a sixth conductive line disposed on the fifth conductive line, extending in the second direction, and electrically connected to the first semiconductor pattern, and a seventh conductive line disposed on the fifth conductive line, extending in the second direction, overlapping the line portion of the second conductive pattern, and electrically connected to the second conductive pattern.

The display panel may further include a first connection pattern disposed on a same layer as the third conductive pattern, located between the first semiconductor pattern and the sixth conductive line, and electrically connected to the first semiconductor pattern through a first contact hole.

The sixth conductive line may be electrically connected to the first connection pattern through a second contact hole, and the first contact hole may overlap the second contact hole.

The display panel may further include a second connection pattern disposed on a same layer as the third conductive pattern, located between the second conductive pattern and the seventh conductive line, and electrically connected to the second conductive pattern through a third contact hole.

The seventh conductive line may be electrically connected to the second connection pattern through a fourth contact hole, and the third contact hole may overlap the fourth contact hole.

The first connection pattern may be arranged adjacent to the second connection pattern along the first direction.

The display panel may further include a third connection pattern disposed on a same layer as the third conductive pattern and electrically connected to the first conductive pattern through a fifth contact hole, wherein the fifth contact hole and the first contact hole may be arranged along the second direction.

The third connection pattern may be electrically connected to the second semiconductor pattern through a sixth contact hole, and the fifth contact hole and the sixth contact hole may be arranged along the first direction.

In a plan view, the first semiconductor pattern may be arranged in parallel with the second semiconductor pattern.

The first semiconductor pattern may include a silicon semiconductor material, and the second semiconductor pattern may include an oxide semiconductor material.

According to one or more embodiments, a display panel includes a first pixel circuit, a second pixel circuit, and a third pixel circuit arranged adjacent to each other in a first direction and each including a first transistor, a second transistor, a third transistor, a first capacitor, and a second capacitor, all of which are disposed on a substrate, a first light-emitting element, a second light-emitting element, and a third light-emitting element electrically connected to the first pixel circuit, the second pixel circuit, and the third pixel circuit, respectively, and emitting light of different respective colors, a first conductive pattern including a line portion and branch portions, wherein the line portion is disposed on a gate electrode of the first transistor, disposed under a semiconductor layer of the second transistor, and extends in the first direction, and the branch portions respectively extend from the line portion in a second direction perpendicular to the first direction, a first gate line disposed on the semiconductor layer of the second transistor, extending in the first direction, and configured to transmit a first gate signal to a gate electrode of the second transistor, a second gate line disposed on a same layer as the first gate line, extending in the first direction, and configured to transmit a second gate signal to a gate electrode of the third transistor, a second conductive pattern disposed on the first gate line, including a first portion overlapping the first gate line, a second portion overlapping the second gate line, and a third portion located between the first portion and the second portion, and electrically connected to each of the semiconductor layer of the second transistor and a semiconductor layer of the third transistor, a data line disposed on the second conductive pattern, extending in the second direction, including a first portion overlapping the second conductive pattern, and configured to transmit a data signal, a driving voltage line disposed on the data line, extending in the first direction, and electrically connected to a semiconductor layer of the first transistor, and an initialization voltage line disposed on a same layer as the driving voltage line, extending in the first direction, overlapping the line portion of the first conductive pattern, and electrically connected to the first conductive pattern.

Each of the semiconductor layer of the first transistor and the semiconductor layer of the second transistor may extend in the second direction.

The semiconductor layer of the first transistor may include a silicon semiconductor material, and the semiconductor layer of the second transistor may include an oxide semiconductor material.

The second capacitor may include the second conductive pattern and the first portion of the data line.

The data line may further include a second portion and a third portion which are spaced apart from each other with the first portion of the data line between the second portion and the third portion, and each of the second portion and the third portion may extend in the second direction, and a maximum width of the first portion of the data line in the first direction may be greater than each of a maximum width of the second portion of the data line in the first direction and a maximum width of the third portion of the data line in the first direction.

The display panel may further include a first connection pattern disposed on a same layer as the second conductive pattern and electrically connecting the driving voltage line to the semiconductor layer of the first transistor, and a second connection pattern disposed on a same layer as the second conductive pattern and electrically connecting the first conductive pattern to the initialization voltage line, wherein the first connection pattern may be arranged adjacent to the second connection pattern along the second direction.

The display panel may further include a third connection pattern disposed on a same layer as the second conductive pattern and electrically connecting the gate electrode of the first transistor to the semiconductor layer of the second transistor.

The first connection pattern may be electrically connected to the semiconductor layer of the first transistor through a first contact hole, the second connection pattern may be electrically connected to the first conductive pattern through a second contact hole, the third connection pattern may be electrically connected to the gate electrode of the first transistor through a third contact hole and may be electrically connected to the semiconductor layer of the second transistor through a fourth contact hole, the first contact hole and the third contact hole may be arranged along the first direction, and the third contact hole and the fourth contact hole may be arranged along the second direction.

The driving voltage line may be electrically connected to the first connection pattern through a fifth contact hole, and the fifth contact hole may overlap the first contact hole.

Each of the first light-emitting element, the second light-emitting element, and the third light-emitting element may include a pixel electrode, and the pixel electrodes may each have a hexagonal shape in a plan view.

According to one or more embodiments, an electronic device includes a display panel. The display panel includes a substrate, a first semiconductor pattern disposed on the substrate and extending in a first direction, a first conductive pattern disposed on the first semiconductor pattern and including a portion overlapping the first semiconductor pattern, a second conductive pattern disposed on the first conductive pattern and including a line portion extending in a second direction, which is perpendicular to the first direction, and branch portions extending from the line portion in the first direction and each overlapping the first semiconductor pattern and the first conductive pattern, a first conductive line and a second conductive line respectively disposed on the second conductive pattern and extending in the second direction, a second semiconductor pattern disposed on the first conductive line and the second conductive line and extending in the first direction, a third conductive line disposed on the second semiconductor pattern, extending in the second direction, and overlapping the first conductive line, a fourth conductive line disposed on the second semiconductor pattern, extending in the second direction, and overlapping the second conductive line, a third conductive pattern disposed on the third conductive line and the fourth conductive line and including a first portion overlapping the third conductive line, a second portion overlapping the fourth conductive line, and a third portion located between the first portion and the second portion, a fifth conductive line disposed on the third conductive pattern, extending in the first direction, and including a portion overlapping the third conductive pattern, a sixth conductive line disposed on the fifth conductive line, extending in the second direction, and electrically connected to the first semiconductor pattern, and a seventh conductive line disposed on the fifth conductive line, extending in the second direction, overlapping the line portion of the second conductive pattern, and electrically connected to the second conductive pattern.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display panel according to an embodiment;

FIG. 2 is an equivalent circuit diagram of a pixel included in a display panel, according to an embodiment;

FIG. 3 is a plan view of a first pixel circuit, a second pixel circuit, and a third pixel circuit of a display panel, according to an embodiment;

FIGS. 4 to 14 are plan views illustrating processes of forming the first pixel circuit, the second pixel circuit, and the third pixel circuit illustrated in FIG. 3;

FIG. 15 is a schematic cross-sectional view of a display panel according to an embodiment;

FIG. 16A is a schematic perspective view of an electronic device according to an embodiment; and

FIG. 16B is a schematic exploded view of an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the example embodiments are described herein, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating embodiments of the disclosure are referred to in order to gain a sufficient understanding of the present disclosure, the merits thereof, and the objectives accomplished by the implementation of the disclosure. The disclosure may, however, be embodied in many different forms and should not be construed as being limited to the embodiments set forth herein.

One or more embodiments of the present disclosure will be described more fully with reference to the accompanying drawings, like reference numerals in the drawings denote like elements, and repeated descriptions thereof will not be provided.

It will be understood that although the terms “first,” “second,” and the like may be used herein to describe various components, these components should not be limited by these terms. These components are used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being connected to another layer, region, or component, it can be directly or indirectly connected to the other layer, region, or component. In an example in which a layer, region, or component is referred to as being electrically connected to another layer, region, or component, it can be directly or indirectly electrically connected to the other layer, region, or component.

In the following examples, the x direction, the y direction, and the z direction are not limited to three axes of the rectangular coordinate system, and may be interpreted in a broader sense. For example, the x direction, the y direction, and the z direction may be perpendicular to one another, or may represent different directions that are not perpendicular to one another.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

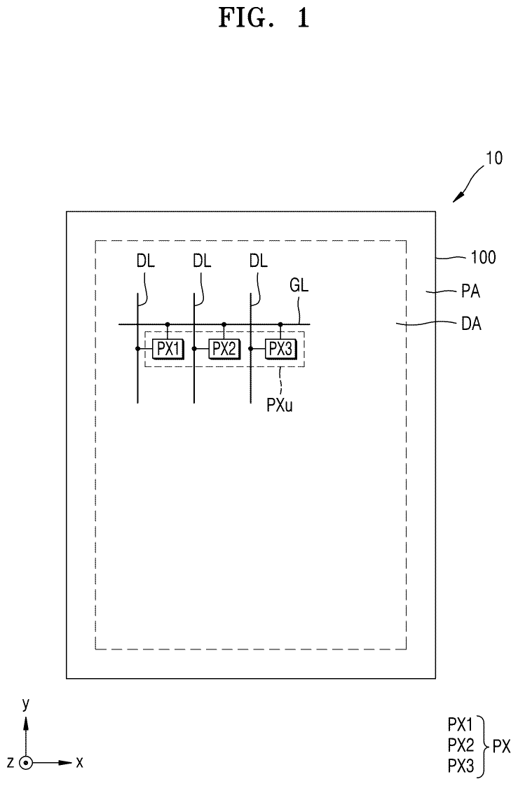

FIG. 1 is a schematic plan view of a display panel 10 according to an embodiment.

Referring to FIG. 1, the display panel 10 may include a display area DA, where images are displayed, and a peripheral area PA outside the display area DA. The display panel 10 may provide certain images by using light emitted from a plurality of pixels arranged in the display area DA. Because the display panel 10 includes a substrate 100, it may be described that the substrate 100 has the display area DA and the peripheral area PA.

In a plan view, the display area DA may have a rectangular shape. In another embodiment, the display area DA may have another polygonal shape, a circular shape, an oval shape, or an atypical shape. In an embodiment, the display area DA may have a shape with rounded corners. In an embodiment, as illustrated in FIG. 1, the display panel 10 may include the display area DA in which the length in a first direction (e.g., a y direction) is greater than that in a second direction (e.g., an x direction). In another embodiment, the display panel 10 may include the display area DA in which the length in the first direction (e.g., the y direction) is less than that in the second direction (e.g., the x direction).

A plurality of pixels PX may be arranged in the display area DA. The plurality of pixels PX may include a first pixel PX1 emitting light of a first color, a second pixel PX2 emitting light of a second color, and a third pixel PX3 emitting light of a third color. For example, the first pixel PX1 may be a red pixel, the second pixel PX2 may be a green pixel, and a third pixel PX3 may be a blue pixel. The first pixel PX1, the second pixel PX2, and the third pixel PX3 may each include a pixel circuit and a light-emitting element electrically connected thereto. The light-emitting elements of the first pixel PX1, the second pixel PX2, and the third pixel PX3 may emit light of different respective colors. The pixel circuit may be a pixel driving circuit that includes a plurality of transistors and at least one capacitor and controls driving of the light-emitting element. A plurality of conductive lines (e.g., gate lines GL, data lines DL, and voltage lines) configured to provide electrical signals to the pixels PX may be arranged in the display area DA.

A unit pixel PXu including the first pixel PX1, the second pixel PX2, and the third pixel PX3 may be repeatedly arranged in the x direction and the y direction according to a certain pattern. The first pixel PX1, the second pixel PX2, and the third pixel PX3 in the unit pixel PXu may be connected to the same gate line GL and may be respectively connected to their corresponding data lines DL.

The peripheral area PA may be an area near the display area DA and surround at least a portion of the display area DA. In an embodiment, the peripheral area PA may be a non-display area where no pixels are arranged. In the peripheral area PA, various lines configured to transmit electrical signals to be applied to the display area DA, circuits, and pads to which a printed circuit board or a driver IC chip is attached may be located.

The display panel 10 according to one or more embodiments may be a device on which a moving image or a still image is displayed and may be used in a portable electronic device, such as, for example, a mobile phone, a laptop, a tablet personal computer (PC), a smartphone, a mobile communication terminal, an electronic organizer, an e-book terminal, a portable multimedia player (PMP), a navigation device, or an ultra-mobile PC (UMPC). Alternatively, the display panel 10 may be used in an electronic device for a television (TV), a monitor, a billboard, or an Internet of Things (IOT) device, or a wearable electronic device, such as, for example, a smartwatch, a watch phone, an eyewear display, or a head-mounted display (HMD). In some aspects, in an embodiment, the display panel 10 may be used in an electronic device for display in an instrument cluster of a vehicle, a center information display (CID) mounted on a center fascia or a dashboard of a vehicle, a room mirror display replacing side-view mirrors of a vehicle, or a car headrest monitor provided for rear-seat entertainment.

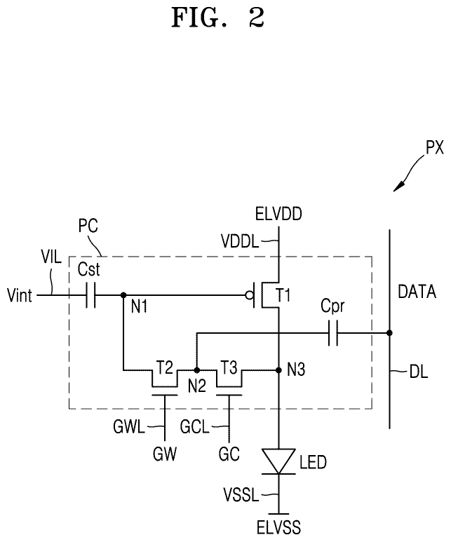

FIG. 2 is an equivalent circuit diagram of a pixel PX included in the display panel (10, see FIG. 1), according to an embodiment.

Referring to FIG. 2, the pixel PX may include a light-emitting element LED and a pixel circuit PC connected to the light-emitting element LED. The pixel circuit PC may include a first transistor T1 to a third transistor T3, a first capacitor Cst, and a second capacitor Cpr.

The first transistor T1 may be a driving transistor configured to output a driving current corresponding to a data signal, and the second transistor T2 and the third transistor T3 may each be a switching transistor configured to transmit a signal. A first electrode and a second electrode of each of the first transistor T1 to the third transistor T3 may be a source electrode and a drain electrode, according to the voltages of the first electrode and the second electrode. For example, according to the voltages of the first electrode and the second electrode, the first electrode may be a source and the second electrode may be a drain, or the first electrode may be a drain and the second electrode may be a source. Hereinafter, a node connected to a gate electrode of the first transistor T1 and a first capacitor electrode of the first capacitor Cst may be defined as a first node N1, a node connected to the first electrode of the second transistor T2 and a third capacitor electrode of the second capacitor Cpr may be defined as a second node N2, and a node connected to the second electrode of the first transistor T1 and the first electrode of the third transistor T3 may be defined as a third node N3.

The pixel PX may be connected to a first gate line GWL configured to transmit a first gate signal GW, a second gate line GCL configured to transmit a second gate signal GC, and a data line DL configured to transmit a data signal DATA. In some aspects, the pixel PX may be connected to a first driving voltage line VDDL configured to transmit a first driving voltage ELVDD, a second driving voltage line VSSL configured to transmit a second driving voltage ELVSS, and an initialization voltage line VIL configured to transmit an initialization voltage Vint.

The first transistor T1 may be connected between the first driving voltage line VDDL and the light-emitting element LED. The gate electrode of the first transistor T1 may be connected to the first node N1. The gate electrode of the first transistor T1 may be connected to the first capacitor electrode of the first capacitor Cst and the second electrode of the second transistor T2 through the first node N1. The first electrode of the first transistor T1 may be connected to the first driving voltage line VDDL. The second electrode of the first transistor T1 may be connected to the third node N3. The second electrode of the first transistor T1 may be connected to the first electrode of the third transistor T3 and a first electrode (e.g., a pixel electrode) of the light-emitting element LED through the third node N3. The first transistor T1 may receive the data signal DATA according to a switching operation of the second transistor T2 and the third transistor T3 and may control the amount of driving currents flowing to the light-emitting element LED.

The second transistor T2 may be connected between the first node N1 and the second node N2. The gate electrode of the second transistor T2 may be connected to the first gate line GWL. The first electrode of the second transistor T2 may be connected to the second node N2 and thus to the data line DL through the second capacitor Cpr. The second electrode of the second transistor T2 may be connected to the first node N1 and thus to the first capacitor electrode of the first capacitor Cst and the gate electrode of the first transistor T1. The second transistor T2 may be turned on in response to the first gate signal GW transmitted through the first gate line GWL and may electrically connect the second capacitor Cpr to the first capacitor Cst, thus transmitting the data signal DATA, which is transmitted through the data line DL, to the gate electrode of the first transistor T1.

The third transistor T3 may be connected between the second node N2 and the third node N3. The third transistor T3 may include a gate electrode connected to the second gate line GCL. The first electrode of the third transistor T3 may be connected to the third node N3. The first electrode of the third transistor T3 may be connected to the second electrode of the first transistor T1 and the first electrode (e.g., the pixel electrode) of the light-emitting element LED through the third node N3. The second electrode of the third transistor T3 may be connected to the second node N2. The second electrode of the third transistor T3 may be connected to a third capacitor electrode of the second capacitor Cpr and the first electrode of the second transistor T2 through the second node N2. The third transistor T3 may be turned on in response to the second gate signal GC, which is transmitted through the second gate line GCL, and diode-connect the second transistor T2 to the first transistor T1, thus compensating for the threshold voltage of the first transistor T1.

The first capacitor Cst may be connected between the first node N1 and the initialization voltage line VIL. The first capacitor Cst may include the first capacitor electrode and a second capacitor electrode. The first capacitor electrode of the first capacitor Cst may be connected to the first node N1 and thus to the gate electrode of the first transistor T1 and the second electrode of the second transistor T2. The second capacitor electrode of the first capacitor Cst may be connected to the initialization voltage line VIL. As a storage capacitor, the first capacitor Cst may store the threshold voltage of the first transistor T1 and a voltage corresponding to the data signal DATA. The first capacitor Cst may change the voltage at the first node N1 in accordance with the voltage change in the initialization voltage line VIL.

The second capacitor Cpr may be connected between the second node N2 and the data line DL. The second capacitor Cpr may include a third capacitor electrode and a fourth capacitor electrode. The third capacitor electrode of the second capacitor Cpr may be connected to the second node N2 and thus to the first electrode of the second transistor T2 and the second electrode of the third transistor T3. The fourth capacitor electrode of the second capacitor Cpr may be connected to the data line DL. The second capacitor Cpr may change the voltage of the second node N2 according to the voltage change in the data line DL.

The light-emitting element LED may be connected between the first transistor T1 and the second driving voltage line VSSL. The light-emitting element LED may include the first electrode (e.g., a pixel electrode or an anode) and the second electrode (e.g., an opposite electrode or a cathode). The first electrode of the light-emitting element LED may be connected to the third node N3 and thus to the second electrode of the first transistor T1 and the first electrode of the third transistor T3. The second electrode of the light-emitting element LED may be connected to the second driving voltage line VSSL configured to provide the second driving voltage ELVSS. The light-emitting element LED may emit light at a luminance corresponding to the driving current provided from the first transistor T1.

The pixel PX may perform initialization, threshold voltage compensation, data writing, and emission during one frame. Initialization of the light-emitting element LED may be additionally performed before emission. In an initialization section and a threshold voltage compensation section, the second transistor T2 and the third transistor T3 operate together such that the voltage at the first electrode of the light-emitting element LED and the voltage at the gate of the first transistor T1 may be initialized and the threshold voltage may be compensated for in the first capacitor Cst. For example, in the threshold voltage compensation section, the voltage at the first node N1 may have a value of ‘ELVDD_H−|VTH|.’ Here, ‘VTH’ is the threshold voltage, and ‘ELVDD_H’ may be a high-voltage value of the first driving voltage ELVDD.

In the data writing section, as the pixels are scanned along rows, the first gate signal GW at a low level may be sequentially applied to the second transistor T2 of each pixel circuit PC. In some aspects, in the data writing section, a data voltage (Vdata) may be sequentially applied to the data line DL of each pixel circuit PC. In this case, in the data writing section, the second transistor T2 may be turned on, and the second transistor T2 may be configured to transmit the data voltage, which is transmitted through the second capacitor Cpr, to the gate of the first transistor T1. In this case, the first capacitor Cst may serve to store and maintain the data voltage transmitted to the gate of the first transistor T1 through the second transistor T2.

As described herein, the third capacitor electrode of the second capacitor Cpr may be connected to the second node N2, and the fourth capacitor electrode may be connected to the data line DL. Accordingly, the voltage at the second node N2 may change according to the change in the voltage at the data line DL, and as the second transistor T2 is turned on, the data voltage at the second node N2 may be stored in the first capacitor Cst. In this case, because the voltage variation transmitted to the second node N2 is transmitted through the second capacitor Cpr, the variation in the voltage applied to the data line DL may be reduced when transmitted. For example, in the data writing section, the voltage at the first node N1 may have a value of ‘EVLDD_L−|VTH|+a×Vdata’ due to charge sharing between the first node N1 and the second node N2 and coupling through the second capacitor Cpr. Here, ‘ELVDD_L’ may be a low-level value of the first driving voltage ELVDD, and ‘a’ may be ‘CprF/CstF+CprF.’ ‘CstF’ may be capacitance of the first capacitor Cst, and ‘CprF’ may be capacitance of the second capacitor Cpr.

In the emission section, the first transistor T1 may be turned on, and the second transistor T2 and the third transistor T3 may be turned off such that the light-emitting element LED may emit light by using the current flowing through the first transistor T1. In this case, the light-emitting element LED may emit light when the data voltage is stored in the first capacitor electrode of the first capacitor Cst and the initialization voltage Vint changes from a low voltage to a high voltage. In other words, after the data writing sections for all pixels are completed, the pixels may simultaneously enter the emission section.

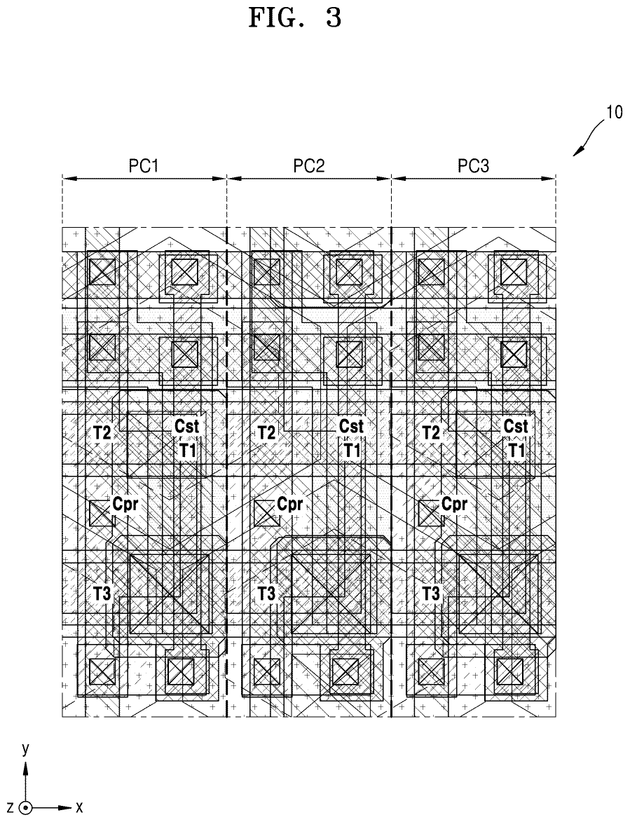

FIG. 3 is a plan view of a first pixel circuit PC1 to a third pixel circuit PC3 of the display panel 10, according to an embodiment. The first pixel circuit PC1, the second pixel circuit PC2, and the third pixel circuit PC3 illustrated in FIG. 3 may be respectively included in the first pixel PX1, the second pixel PX2, and the third pixel PX3 in the unit pixel PXu of FIG. 1. The first pixel circuit PC1, the second pixel circuit PC2, and the third pixel circuit PC3 may be arranged in the second direction (e.g., the x direction).

Referring to FIG. 3, the first pixel circuit PC1, the second pixel circuit PC2, and the third pixel circuit PC3 may each include a plurality of transistors and a capacitor. In some embodiments, FIG. 3 illustrates that each of the first pixel circuit PC1, the second pixel circuit PC2, and the third pixel circuit PC3 includes three transistors, that is, the first transistor T1 to the third transistor T3, the first capacitor Cst, and the second capacitor Cpr, which are described with reference to FIG. 2.

The first transistor T1 may overlap the first capacitor Cst. Switching transistors (e.g., the second transistor T2 and the third transistor T3) may be disposed on the left side of the plane with respect to the first transistor T1 and/or the first capacitor Cst. The second capacitor Cpr may be arranged between the second transistor T2 and the third transistor T3, and a portion of the second capacitor Cpr may overlap the second transistor T2, while another portion of the second capacitor Cpr may overlap the third transistor T3.

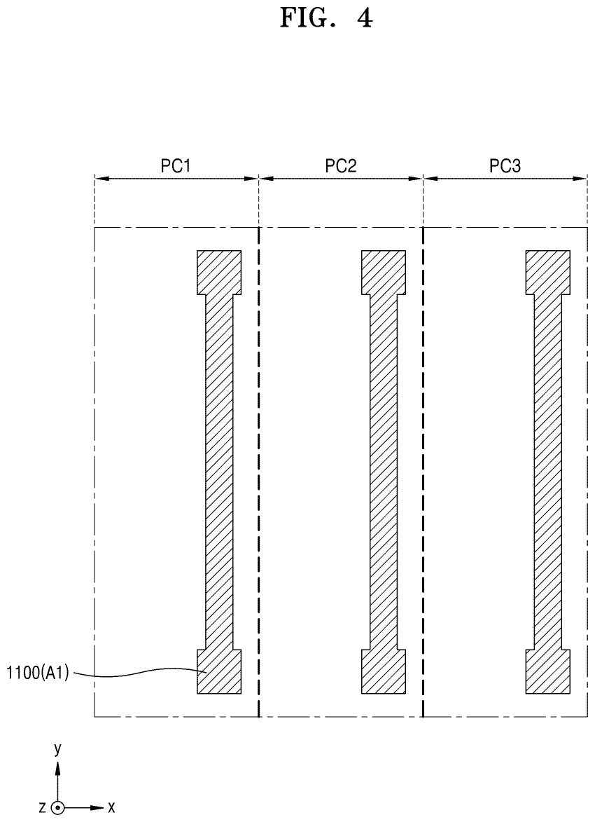

FIGS. 4 to 14 are plan views according to the processes of forming the first pixel circuit PC1 to the third pixel circuit PC3 illustrated in FIG. 3.

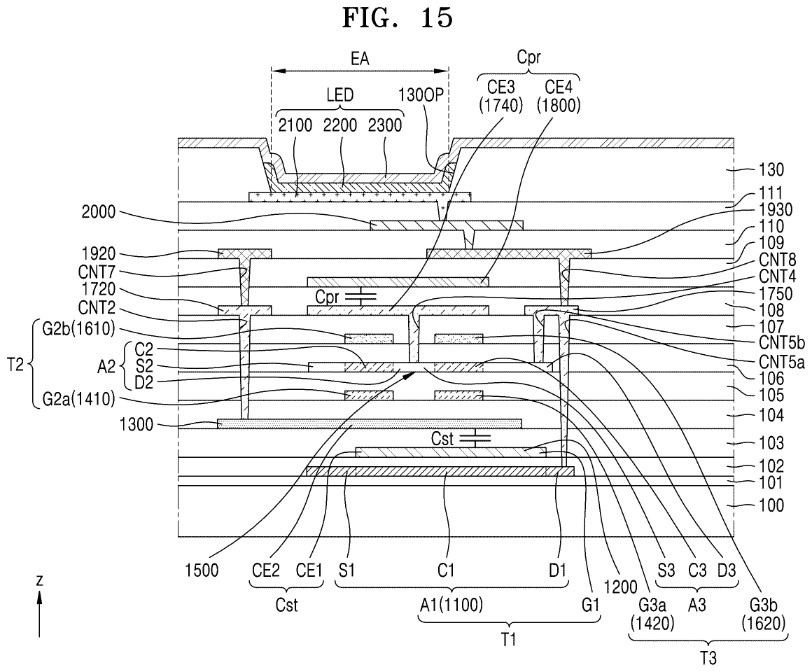

Referring to FIG. 4, first semiconductor patterns 1100 may be disposed on the substrate (100, see FIG. 15). The first semiconductor patterns 1100 may be arranged corresponding to the first pixel circuit PC1 to the third pixel circuit PC3, respectively.

The first semiconductor pattern 1100 may extend in the first direction (e.g., the y direction). The first semiconductor pattern 1100 may include a semiconductor layer A1 of the first transistor (T1, see FIG. 2).

The first semiconductor pattern 1100 may include a silicon semiconductor material. The first semiconductor pattern 1100 may include amorphous silicon or polysilicon. For example, the first semiconductor pattern 1100 may include polysilicon crystallized at a low temperature.

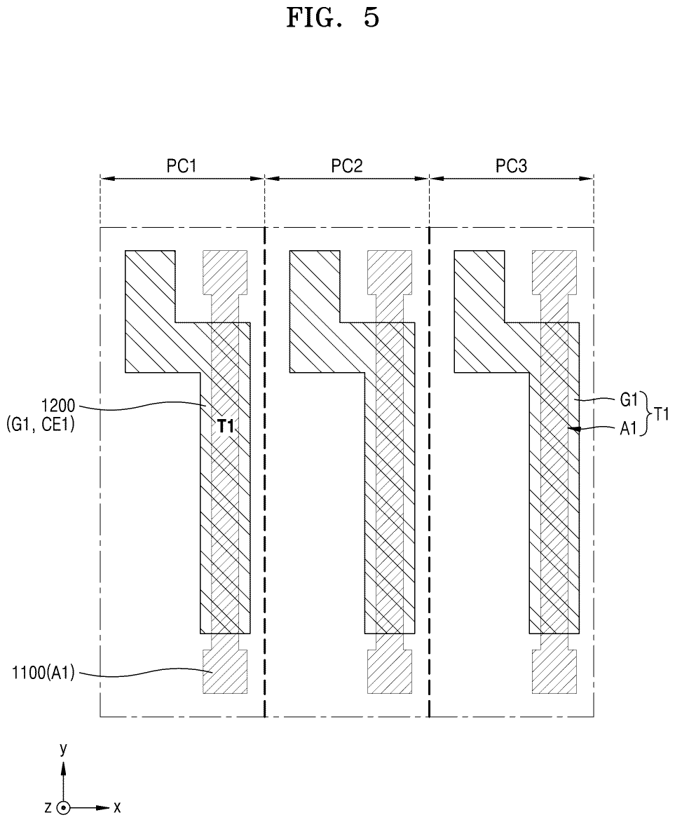

Referring to FIGS. 4 and 5, a first insulating layer (102, see FIG. 15) may be disposed on the first semiconductor pattern 1100, and a first conductive pattern 1200 may be disposed on the first insulating layer (102, see FIG. 15). The first conductive pattern 1200 may be arranged corresponding to each of the first pixel circuit PC1 to the third pixel circuit PC3.

The first conductive pattern 1200 may include a gate electrode G1 of the first transistor T1. The semiconductor layer A1 of the first transistor T1 may include a channel area, which overlaps the first conductive pattern 1200 that is the gate electrode G1 of the first transistor T1, and a source area and a drain area on opposite sides of the channel area.

The first conductive pattern 1200 may be bent. For example, the first conductive pattern 1200 may include a first portion, which corresponds to the gate electrode G1 of the first transistor T1 extending in the first direction (e.g., the y direction) and overlaps the first semiconductor pattern 1100, and a second portion which is bent in an ‘L’ shape from the first portion corresponding to the gate electrode G1.

In an embodiment, the first conductive pattern 1200 may include a first lower electrode CE1 of the first capacitor (Cst, see FIG. 2). The first conductive pattern 1200 may be the gate electrode G1 of the first transistor T1 and/or the first lower electrode CE1 of the first capacitor (Cst, see FIG. 2).

The shape of the channel area of the semiconductor layer A1 of the first transistor T1 of each of the first pixel circuit PC1 to the third pixel circuit PC3 may be a straight line extending in the first direction (e.g., the y direction).

The first conductive pattern 1200 may include a conductive material such as, for example, aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and may be a layer or layers including the aforementioned material.

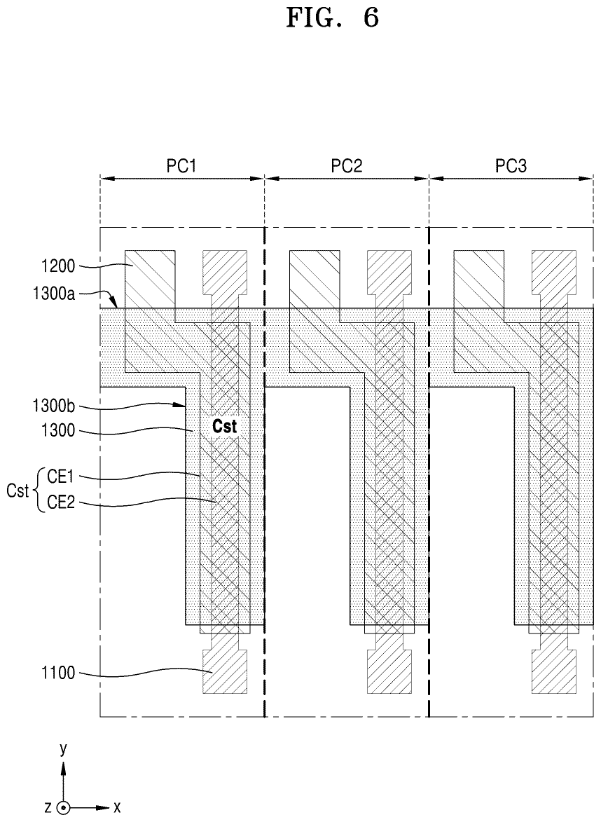

Referring to FIGS. 5 and 6, a second insulating layer (103, see FIG. 15) may be disposed on the first conductive pattern 1200, and a second conductive pattern 1300 may be disposed on the second insulating layer (103, see FIG. 15).

The second conductive pattern 1300 may include a line portion 1300a extending in the second direction (e.g., the x direction) and passing the first pixel circuit PC1 to the third pixel circuit PC3 along the second direction (e.g., the x direction). The second conductive pattern 1300 may include branch portions 1300b that extend from the line portion 1300a in the first direction (e.g., the y direction) and respectively correspond to the first pixel circuit PC1 to the third pixel circuit PC3. The branch portions 1300b of the second conductive pattern 1300 may overlap the first semiconductor pattern 1100 and the first conductive pattern 1200.

The second conductive pattern 1300 may overlap the first conductive pattern 1200. A portion of the first conductive pattern 1200, which overlaps the second conductive pattern 1300, may correspond to the first lower electrode CE1 of the first capacitor Cst, and a portion of the second conductive pattern 1300, which overlaps the first conductive pattern 1200, may correspond to a first upper electrode CE2 of the first capacitor Cst. The first upper electrode CE2 of the first capacitor Cst may include the branch portion 1300b of the second conductive pattern 1300.

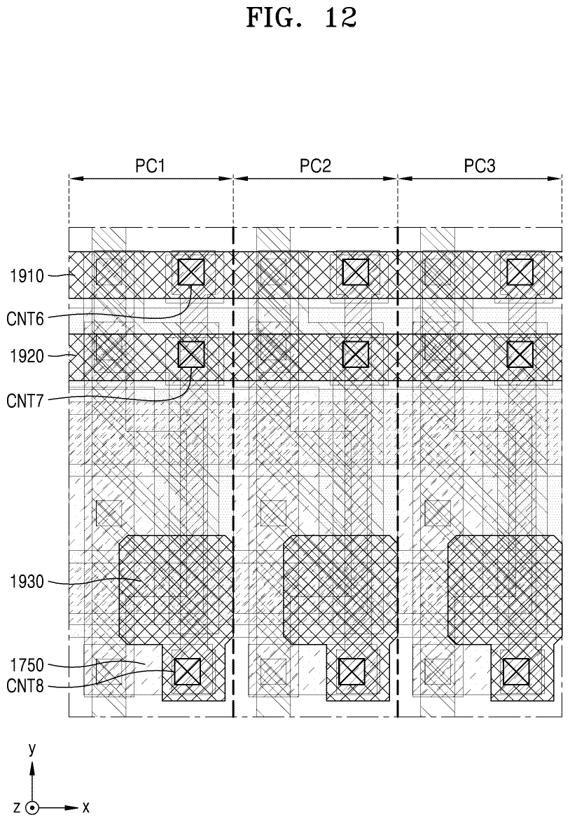

The second conductive pattern 1300 may be electrically connected to a seventh conductive line 1920 (see FIG. 12) described herein, thus receiving an initialization voltage Vint (see FIG. 2). In other words, the first upper electrode CE2 of the first capacitor Cst may receive the initialization voltage Vint.

The second conductive pattern 1300 may include a conductive material, for example, Al, Pt, Pd, Ag, Mg, Au, Ni, Nd, Ir, Cr, Li, Ca, Mo, Ti, W, and/or Cu, and may be a layer or layers including the aforementioned material.

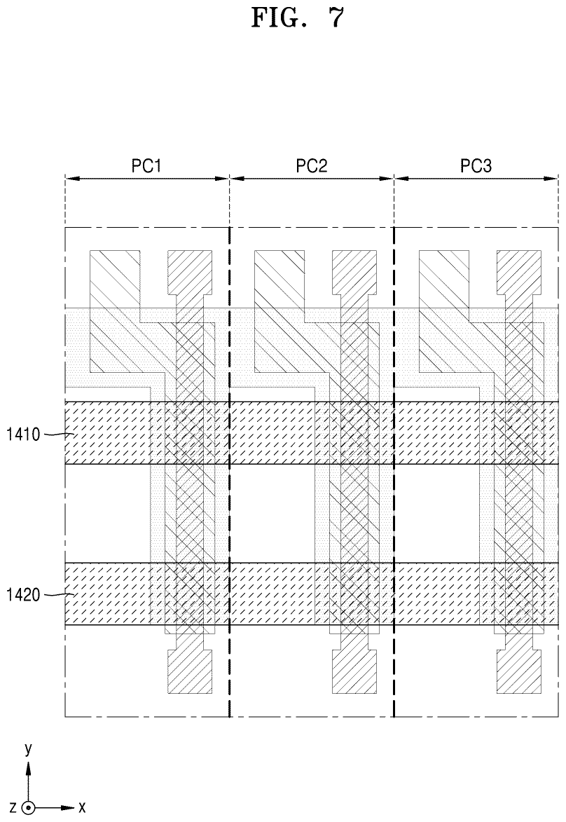

Referring to FIGS. 6 and 7, a third insulating layer (104, see FIG. 15) may be disposed on the second conductive pattern 1300, and a first conductive line 1410 and a second conductive line 1420 may be disposed on the third insulating layer (104, see FIG. 15). The first conductive line 1410 and the second conductive line 1420 may include the same material and may be disposed on the same layer (e.g., the third insulating layer (104, see FIG. 15)).

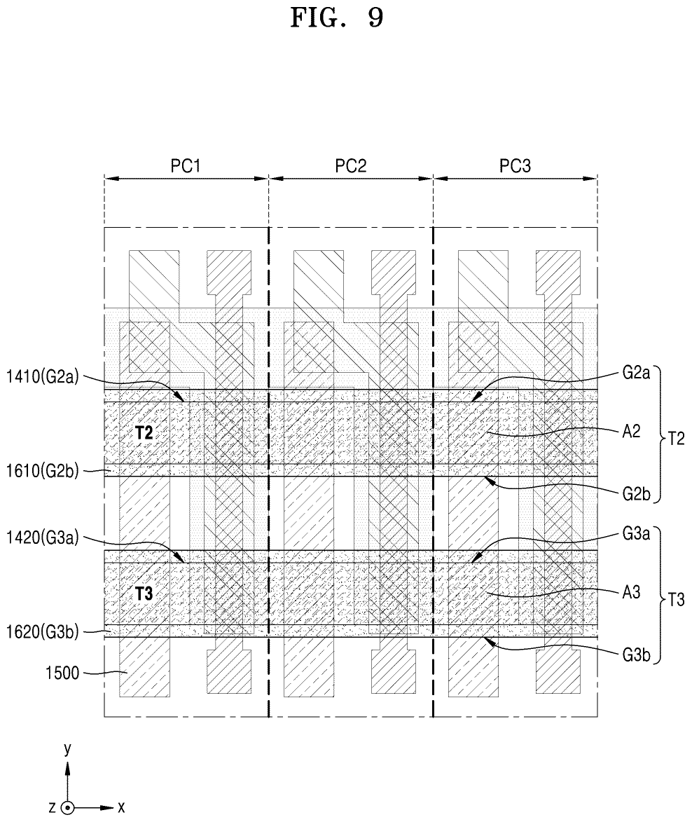

The first conductive line 1410 may extend in the second direction (e.g., the x direction) and pass the first pixel circuit PC1 to the third pixel circuit PC3. The first conductive line 1410 may include a lower gate electrode (G2a, see FIG. 9) of the second transistor (T2, see FIG. 9) described herein.

The second conductive line 1420 may extend in the second direction (e.g., the x direction) and pass the first pixel circuit PC1 to the third pixel circuit PC3. The second conductive line 1420 may include a lower gate electrode (G3a, see FIG. 9) of the third transistor (T3, see FIG. 9) described herein.

Each of the first conductive line 1410 and the second conductive line 1420 may include a conductive material, for example, Al, Pt, Pd, Ag, Mg, Au, Ni, Nd, Ir, Cr, Li, Ca, Mo, Ti, W, and/or Cu and may be a layer or layers including the aforementioned material.

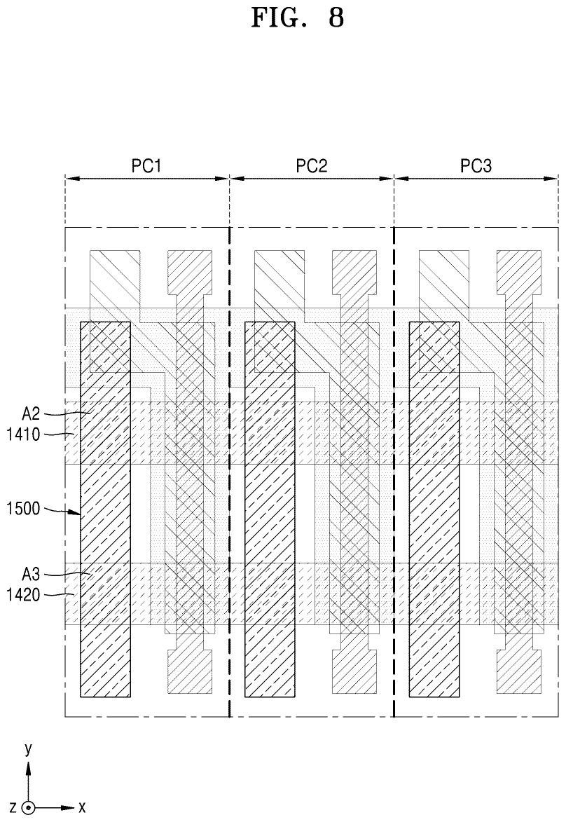

Referring to FIGS. 7 and 8, a fourth insulating layer (105, see FIG. 15) may be disposed on the first conductive line 1410 and the second conductive line 1420, and the second semiconductor pattern 1500 may be disposed on the fourth insulating layer (105, see FIG. 15). The second semiconductor pattern 1500 may be arranged corresponding to each of the first pixel circuit PC1 to the third pixel circuit PC3.

The second semiconductor pattern 1500 may extend in the first direction (e.g., the y direction). The second semiconductor pattern 1500 may be arranged such that the second semiconductor pattern 1500 crosses each of the first conductive line 1410 and the second conductive line 1420. The second semiconductor pattern 1500 may include a semiconductor layer A2 of the second transistor (T2, see FIG. 2) and a semiconductor layer A3 of the third transistor (T3, see FIG. 2).

The second semiconductor pattern 1500 may not overlap the first semiconductor pattern 1100. In a plan view, the second semiconductor pattern 1500 may be arranged in parallel with the first semiconductor pattern 1100. In a plan view, for example, the first semiconductor pattern 1100 and the second semiconductor pattern 1500 may extend in the first direction (e.g., the y direction) and may be spaced apart from each other in the second direction (e.g., the x direction).

In a plan view, because the second semiconductor pattern 1500 is arranged in parallel with the first semiconductor pattern 1100, the generation of parasitic capacitance between the electrodes of the transistors, voltage lines, and/or signal lines of the first pixel circuit PC1 to the third pixel circuit PC3 in a limited space may be reduced, and the space may be efficiently utilized (for example, the level of integration is improved).

The second semiconductor pattern 1500 may include an oxide semiconductor material. For example, the second semiconductor pattern 1500 may include oxide of at least one material selected from the group consisting of indium (In), gallium (Ga), stannum (Sn), zirconium (Zr), vanadium (V), hafnium (Hf), cadmium (Cd), germanium (Ge), Cr, Ti, Al, cesium (Cs), cerium (Ce), and zinc (Zn). For example, the second semiconductor pattern 1500 may include InSnZnO (ITZO), InGaZnO (IGZO), or the like. Because the oxide semiconductor has a wide band gap (about 3.1 eV), high carrier mobility, and a low leakage current, a voltage drop may not be great despite a long operation time, and thus, a brightness change according to the voltage drop may not be great even during operation in a low frequency.

Referring to FIGS. 8 and 9, a fifth insulating layer (106, see FIG. 15) may be disposed on the second semiconductor pattern 1500, and a third conductive line 1610 and a fourth conductive line 1620 may be disposed on the fifth insulating layer (106, see FIG. 15). The third conductive line 1610 and the fourth conductive line 1620 may include the same material and may be disposed on the same layer (e.g., the fifth insulating layer (106, see FIG. 15)).

The third conductive line 1610 may extend in the second direction (e.g., the x direction) and pass the first pixel circuit PC1 to the third pixel circuit PC3. The third conductive line 1610 may overlap the first conductive line 1410. The third conductive line 1610 may be the first gate line (GWL, see FIG. 2) configured to transmit the first gate signal (GW, see FIG. 2).

The first conductive line 1410 may include a portion of the second semiconductor pattern 1500, for example, the lower gate electrode G2a overlapping the semiconductor layer A2 of the second transistor T2. The third conductive line 1610 may include a portion of the second semiconductor pattern 1500, for example, an upper gate electrode G2b overlapping the semiconductor layer A2 of the second transistor T2.

The fourth conductive line 1620 may extend in the second direction (e.g., the x direction) and pass the first pixel circuit PC1 to the third pixel circuit PC3. The fourth conductive line 1620 may overlap the second conductive line 1420. The fourth conductive line 1620 may be the second gate line (GCL, see FIG. 2) configured to transmit the second gate signal (GC, see FIG. 2).

The second conductive line 1420 may include a portion of the second semiconductor pattern 1500, for example, the lower gate electrode G3a overlapping the semiconductor layer A3 of the third transistor T3. The fourth conductive line 1620 may include a portion of the second semiconductor pattern 1500, for example, an upper gate electrode G3b overlapping the semiconductor layer A3 of the third transistor T3.

Because the first conductive line 1410 overlaps the third conductive line 1610 and the second conductive line 1420 overlaps the fourth conductive line 1620, the generation of parasitic capacitance between the electrodes of the transistors, voltage lines, and/or signal lines of the first pixel circuit PC1 to the third pixel circuit PC3 in a limited space may be reduced, and the space may be efficiently utilized (for example, the level of integration is improved).

The semiconductor layer A2 of the second transistor T2 arranged in each of the first pixel circuit PC1 to the third pixel circuit PC3 may include a channel area, which overlaps the first conductive line 1410 disposed under the semiconductor layer A2 of the second transistor T2 and the third conductive line 1610 disposed on the semiconductor layer A2 of the second transistor T2, and a source area and a drain area on opposite sides of the channel area.

The semiconductor layer A3 of the third transistor T3 arranged in each of the first pixel circuit PC1 to the third pixel circuit PC3 may include a channel area, which overlaps the second conductive line 1420 disposed under the semiconductor layer A3 of the third transistor T3 and the fourth conductive line 1620 disposed on the semiconductor layer A3 of the third transistor T3, and a source area and a drain area on opposite sides of the channel area.

FIG. 9 illustrates that the second transistor T2 includes a dual-gate electrode including the lower gate electrode G2a and the upper gate electrode G2b and the third transistor T3 includes a dual-gate electrode including the lower gate electrode G3a and the upper gate electrode G3b, but one or more embodiments are not limited thereto. In another embodiment, the second transistor T2 may include one of the lower gate electrode G2a and the upper gate electrode G2b, and the third transistor T3 may include one of the lower gate electrode G3a and the upper gate electrode G3b.

Each of the third conductive line 1610 and the fourth conductive line 1620 may include a conductive material, for example, Al, Pt, Pd, Ag, Mg, Au, Ni, Nd, Ir, Cr, Li, Ca, Mo, Ti, W, and/or Cu and may be a layer or layers including the aforementioned material.

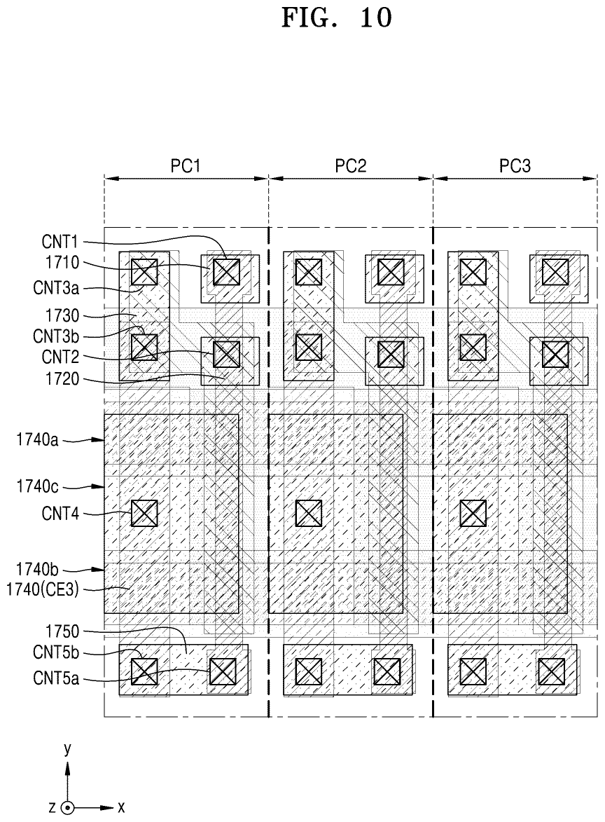

Referring to FIGS. 9 and 10, a sixth insulating layer (107, see FIG. 15) may be disposed on the third conductive line 1610 and the fourth conductive line 1620, and a first connection pattern 1710, a second connection pattern 1720, a third connection pattern 1730, a fourth connection pattern 1750, and a third conductive pattern 1740 may be disposed on the sixth insulating layer (107, see FIG. 15). The first connection pattern 1710, the second connection pattern 1720, the third connection pattern 1730, the fourth connection pattern 1750, and the third conductive pattern 1740 may include the same material and may be disposed on the same layer (e.g., the sixth insulating layer (107, see FIG. 15)). Each of the first connection pattern 1710, the second connection pattern 1720, the third connection pattern 1730, the fourth connection pattern 1750, and the third conductive pattern 1740 may be arranged corresponding to each of the first pixel circuit PC1 to the third pixel circuit PC3.

The first connection pattern 1710 may be between the first semiconductor pattern (1100, see FIG. 4) and a sixth conductive line (1910, see FIG. 12) described herein. The first connection pattern 1710 may electrically connect the first semiconductor pattern (1100, see FIG. 4) to the sixth conductive line (1910, see FIG. 12) described herein. The first connection pattern 1710 may be connected (e.g., electrically or physically connected) to the first semiconductor pattern (1100, see FIG. 4) through a first contact hole CNT1.

The second connection pattern 1720 may be between the second conductive pattern (1300, see FIG. 6) and the seventh conductive line (1920, see FIG. 12) described herein. The second connection pattern 1720 may electrically connect the second conductive pattern (1300, see FIG. 6) to the seventh conductive line (1920, see FIG. 12). The second connection pattern 1720 may be connected (e.g., electrically or physically connected) to the second conductive pattern (1300, see FIG. 6) through a second contact hole CNT2.

The third connection pattern 1730 may overlap a portion of the first conductive pattern (1200, see FIG. 5) and a portion of the second semiconductor pattern (1500, see FIG. 8). The third connection pattern 1730 may electrically connect the first conductive pattern (1200, see FIG. 5) to the second semiconductor pattern (1500, see FIG. 8). The third connection pattern 1730 may electrically connect the gate electrode (G1, see FIG. 5) of the first transistor (T1, see FIG. 5) to the semiconductor layer (A2, see FIG. 9) of the second transistor (T2, see FIG. 9). The third connection pattern 1730 may be connected (e.g., electrically or physically connected) to the first conductive pattern (1200, see FIG. 5) through a 3^{rd}-1 contact hole CNT3a. The third connection pattern 1730 may be connected (e.g., electrically or physically connected) to the second semiconductor pattern (1500, see FIG. 8) through a 3^{rd}-2 contact hole CNT3b.

In a plan view, the first connection pattern 1710 may be arranged adjacent to the second connection pattern 1720 in the first direction (e.g., the y direction). In a plan view, each of the first connection pattern 1710 and the second connection pattern 1720 may be spaced apart from the third connection pattern 1730 in the second direction (e.g., the x direction).

The fourth connection pattern 1750 may overlap a portion of the first semiconductor pattern (1100, see FIG. 4) and a portion of the second semiconductor pattern (1500, see FIG. 8). The fourth connection pattern 1750 may electrically connect the first semiconductor pattern (1100, see FIG. 4) to the second semiconductor pattern (1500, see FIG. 8). The fourth connection pattern 1750 may electrically connect the semiconductor layer (A1, see FIG. 5) of the first transistor (T1, see FIG. 5) to the semiconductor layer (A3, see FIG. 9) of the third transistor (T3, see FIG. 9). The fourth connection pattern 1750 may be connected (e.g., electrically or physically connected) to the first semiconductor pattern (1100, see FIG. 4) through a 5^{th}-1 contact hole CNT5a. The fourth connection pattern 1750 may be connected (e.g., electrically or physically connected) to the second semiconductor pattern (1500, see FIG. 8) through a 5^{th}-2 contact hole CNT5b.

A portion of the fourth connection pattern 1750 may be between the second semiconductor pattern (1500, see FIG. 8) and a first pixel connection pattern (1930, see FIG. 12) that is electrically connected to the pixel electrode (2100, see FIG. 15).

A portion of the third conductive pattern 1740 may overlap the third conductive line 1610, and another portion of the third conductive pattern 1740 may overlap the fourth conductive line 1620. Similarly, a portion of the third conductive pattern 1740 may overlap the first conductive line 1410, and another portion of the third conductive pattern 1740 may overlap the second conductive line 1420.

In an embodiment, the third conductive pattern 1740 may include a first portion 1740a overlapping the third conductive line 1610, a second portion 1740b overlapping the fourth conductive line 1620, and a third portion 1740c located between the first portion 1740a and the second portion 1740b. In an embodiment, in a plan view, the first portion 1740a, the second portion 1740b, and the third portion 1740c of the third conductive pattern 1740 may each have a rectangular shape.

The third conductive pattern 1740 may be connected (e.g., electrically or physically connected) to the second semiconductor pattern (1500, see FIG. 8) through a fourth contact hole CNT4. The third conductive pattern 1740 may be electrically connected to the semiconductor layer (A2, see FIG. 9) of the second transistor (T2, see FIG. 9) and the semiconductor layer (A3, see FIG. 9) of the third transistor (T3, see FIG. 9).

The third conductive pattern 1740 may be the second lower electrode CE3 of the second capacitor (Cpr, see FIG. 2). The area of the third conductive pattern 1740 may be greater than the area of each of the first connection pattern 1710 to the fourth connection pattern 1750.

In a plan view, the third conductive pattern 1740 may be located between the third connection pattern 1730 and the fourth connection pattern 1750. In a plan view, the third conductive pattern 1740 may be located between the second connection pattern 1720 and the fourth connection pattern 1750.

In a plan view, the first contact hole CNT1 and the second contact hole CNT2 may be arranged along the first direction (e.g., the y direction). In a plan view, the 3^{rd}-1 contact hole CNT3a, the 3^{rd}-2 contact hole CNT3b, the fourth contact hole CNT4, and the 5^{th}-2 contact hole CNT5b may be arranged along the first direction (e.g., the y direction). In a plan view, the 3^{rd}-1 contact hole CNT3a and the first contact hole CNT1 may be arranged along the second direction (e.g., the x direction). In a plan view, the 3^{rd}-2 contact hole CNT3b and the second contact hole CNT2 may be arranged along the second direction (e.g., the x direction). In a plan view, the 5^{th}-1 contact hole CNT5a and the 5^{th}-2 contact hole CNT5b may be arranged along the second direction (e.g., the x direction).

In the present specification, a contact hole may be defined as a through hole penetrating one or more insulating layers. Each of the first connection pattern 1710, the second connection pattern 1720, the third connection pattern 1730, the fourth connection pattern 1750, and the third conductive pattern 1740 may include a contact portion located in a contact hole, and the description given regarding the contact holes in the present specification may be equally understood as the description regarding the contact portions.

Each of the first connection pattern 1710, the second connection pattern 1720, the third connection pattern 1730, the fourth connection pattern 1750, and the third conductive pattern 1740 may have an island pattern. In an embodiment, each of the first connection pattern 1710, the second connection pattern 1720, the third connection pattern 1730, the fourth connection pattern 1750, and the third conductive pattern 1740 may have a rectangular pattern.

Each of the first connection pattern 1710, the second connection pattern 1720, the third connection pattern 1730, the fourth connection pattern 1750, and the third conductive pattern 1740 may include a conductive material, such as, for example, Al, Pt, Pd, Ag, Mg, Au, Ni, Nd, Ir, Cr, Li, Ca, Mo, Ti, W, and/or Cu, and may be a layer or layers including the aforementioned material.

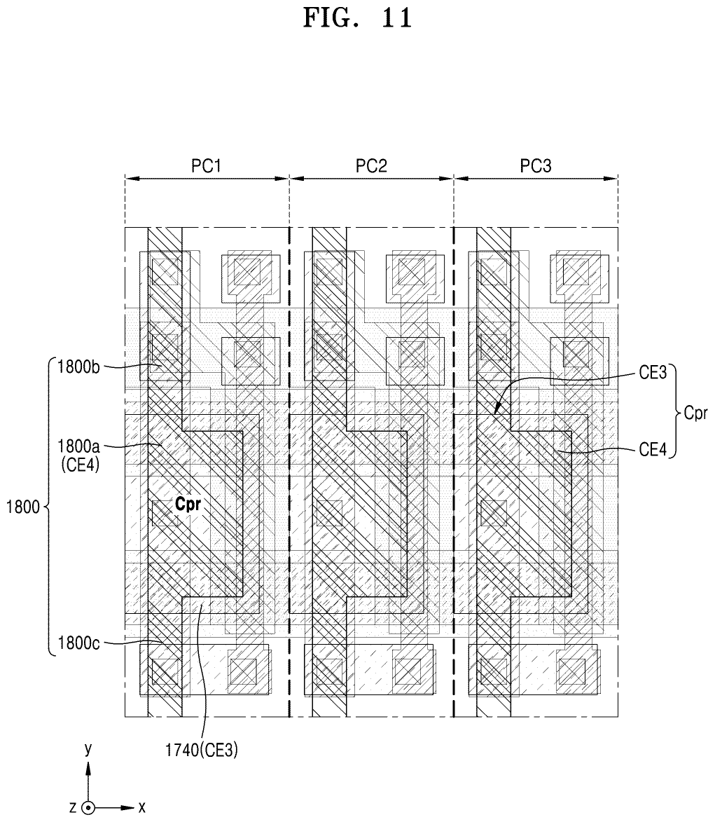

Referring to FIGS. 10 and 11, a seventh insulating layer (108, see FIG. 15) may be disposed on the first connection pattern 1710, the second connection pattern 1720, the third connection pattern 1730, the fourth connection pattern 1750, and the third conductive pattern 1740, and a fifth conductive line 1800 may be disposed on the seventh insulating layer (108, see FIG. 15). The fifth conductive line 1800 may be arranged corresponding to each of the first pixel circuit PC1 to the third pixel circuit PC3.

The fifth conductive line 1800 may extend in the first direction (e.g., the y direction). The fifth conductive line 1800 may be a data line (DL, see FIG. 2) configured to transmit a data signal (DATA, see FIG. 2).

A portion of the fifth conductive line 1800 may overlap the third conductive pattern 1740. In an embodiment, the fifth conductive line 1800 may include a first portion 1800a overlapping the third conductive pattern 1740, and the fifth conductive line 1800 may include a second portion 1800b and a third portion 1800c which respectively extend in the first direction (e.g., the y direction) with the first portion 1800a between the second portion 1800b and the third portion 1800c. The second portion 1800b of the fifth conductive line 1800 may overlap the third connection pattern (1730, see FIG. 10). The third portion 1800c of the fifth conductive line 1800 may overlap the fourth connection pattern (1750, see FIG. 10).

The maximum width of the first portion 1800a of the fifth conductive line 1800 in the second direction (e.g., the x direction) may be greater than the maximum width of the second portion 1800b of the fifth conductive line 1800 in the second direction (e.g., the x direction). The maximum width of the first portion 1800a of the fifth conductive line 1800 in the second direction (e.g., the x direction) may be greater than the maximum width of the third portion 1800c of the fifth conductive line 1800 in the second direction (e.g., the x direction).

The fifth conductive line 1800 may include a second upper electrode CE4 of the second capacitor Cpr. The first portion 1800a of the fifth conductive line 1800, which overlaps the third conductive pattern 1740, may be the second upper electrode CE4 of the second capacitor Cpr. A portion of the third conductive pattern 1740, which overlaps the fifth conductive line 1800, may be the second lower electrode CE3 of the second capacitor Cpr.

The fifth conductive line 1800 may include a conductive material, for example, Al, Pt, Pd, Ag, Mg, Au, Ni, Nd, Ir, Cr, Li, Ca, Mo, Ti, W, and/or Cu, and may be a layer or layers including the aforementioned material.

Referring to FIGS. 11 and 12, a first via insulating layer (109, see FIG. 15) may be disposed on the fifth conductive line 1800, and a sixth conductive line 1910, a seventh conductive line 1920, and a first pixel connection pattern 1930 may be disposed on the first via insulating layer (109, see FIG. 15). The sixth conductive line 1910, the seventh conductive line 1920, and the first pixel connection pattern 1930 may include the same material and may be disposed on the same layer (e.g., the first via insulating layer (109, see FIG. 15)).

Each of the sixth conductive line 1910 and the seventh conductive line 1920 may extend in the second direction (e.g., the x direction) and pass the first pixel circuit PC1 to the third pixel circuit PC3.

The sixth conductive line 1910 may be a first driving voltage line (VDDL, see FIG. 2) configured to transmit a first driving voltage (ELVDD, see FIG. 2). The sixth conductive line 1910 may be electrically connected to the first semiconductor pattern (1100, see FIG. 4) through the first connection pattern (1710, see FIG. 10). That is, the first driving voltage (ELVDD, see FIG. 2) may be transmitted to the first semiconductor pattern (1100, see FIG. 4) (e.g., the semiconductor layer (A1, see FIG. 5) of the first transistor (T1, see FIG. 5)) through the sixth conductive line 1910 and the first connection pattern (1710, see FIG. 10). The sixth conductive line 1910 may be connected (e.g., electrically or physically connected) to the first connection pattern (1710, see FIG. 10) through a sixth contact hole CNT6. The sixth contact hole CNT6 may overlap the first contact hole (CNT1, see FIG. 10).

The seventh conductive line 1920 may be an initialization voltage line (VIL, see FIG. 2) configured to transmit the initialization voltage (Vint, see FIG. 2). The seventh conductive line 1920 may be electrically connected to the second conductive pattern (1300, see FIG. 6) through the second connection pattern (1720, see FIG. 10). In other words, the initialization voltage (Vint, see FIG. 2) may be transmitted to the second conductive pattern (1300, see FIG. 6) through the seventh conductive line 1920 and the second connection pattern (1720, see FIG. 10). The seventh conductive line 1920 may be connected (e.g., electrically or physically connected) to the second connection pattern (1720, see FIG. 10) through a seventh contact hole CNT7. The seventh contact hole CNT7 may overlap the second contact hole (CNT2, see FIG. 10).

The seventh conductive line 1920 may overlap the line portion (1300a, see FIG. 6) of the second conductive pattern (1300, see FIG. 6). As the line portion (1300a, see FIG. 6) of the second conductive pattern (1300, see FIG. 6) and the seventh conductive line 1920 are formed to have line shapes overlapping each other, the generation of parasitic capacitance between the electrodes of the transistors, voltage lines, and/or signal lines of the first pixel circuit PC1 to the third pixel circuit PC3 in a limited space may be reduced, and the space may be efficiently utilized (for example, the level of integration is improved). In some aspects, as the second conductive pattern (1300, see FIG. 6) is electrically connected to the seventh conductive line 1920, the resistance in the initialization voltage line (VIL, see FIG. 2) may be reduced.

The first pixel connection pattern 1930 may be arranged corresponding to each of the first pixel circuit PC1 to the third pixel circuit PC3. The first pixel connection pattern 1930 may be connected (e.g., electrically or physically connected) to the fourth connection pattern 1750 through an eighth contact hole CNT8. The eighth contact hole CNT8 may overlap the 5^{th}-1 contact hole (CNT5a, see FIG. 10).

In the present specification, a contact hole may be defined as a through hole penetrating one or more insulating layers. Each of the sixth conductive line 1910, the seventh conductive line 1920, and the first pixel connection pattern 1930 may include a contact portion disposed in a contact hole, and in the present specification, the description regarding the contact holes may be equally understood as the description regarding the contact portions.

Each of the sixth conductive line 1910, the seventh conductive line 1920, and the first pixel connection pattern 1930 may include a conductive material, such as, for example, Al, Pt, Pd, Ag, Mg, Au, Ni, Nd, Ir, Cr, Li, Ca, Mo, Ti, W, and/or Cu, and may be a layer or layers including the aforementioned material.

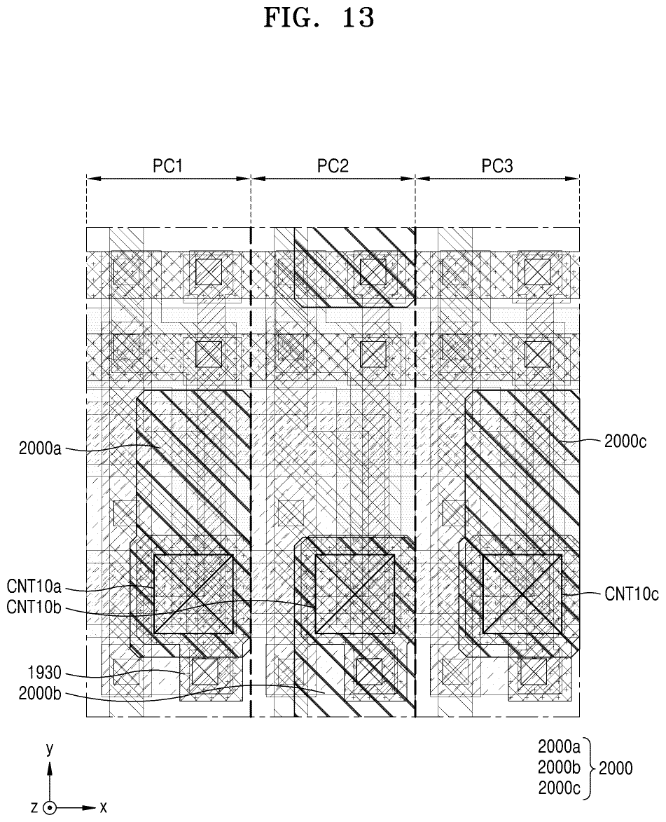

Referring to FIGS. 12 and 13, a second via insulating layer (110, see FIG. 15) may be disposed on the first pixel connection pattern 1930, and a second pixel connection pattern 2000 may be disposed on the second via insulating layer (110, see FIG. 15).

The second pixel connection pattern 2000 may include a 2^{nd}-1 pixel connection pattern 2000a arranged in the first pixel circuit PC1, a 2^{nd}-2 pixel connection pattern 2000b arranged in the second pixel circuit PC2, and a 2^{nd}-3 pixel connection pattern 2000c arranged in the third pixel circuit PC3.

In an embodiment, the 2^{nd}-1 pixel connection pattern 2000a and the 2^{nd}-3 pixel connection pattern 2000c may be arranged at locations corresponding to the first pixel circuit PC1 and the third pixel circuit PC3, respectively. The 2^{nd}-2 pixel connection pattern 2000b may be shifted from the location corresponding to the 2^{nd}-1 pixel connection pattern 2000a along the first direction (e.g., the y direction). For example, in a plan view, the 2^{nd}-1 pixel connection pattern 2000a, the 2^{nd}-2 pixel connection pattern 2000b, and the 2^{nd}-3 pixel connection pattern 2000c may be arranged in a zigzag form along the second direction (e.g., the x direction).

In the first pixel circuit PC1, the 2^{nd}-1 pixel connection pattern 2000a may be connected (e.g., electrically or physically connected) to the first pixel connection pattern 1930 of the first pixel circuit PC1 through a 10^{th}-1 contact hole CNT10a. In the second pixel circuit PC2, the 2^{nd}-2 pixel connection pattern 2000b may be connected (e.g., electrically or physically connected) to the first pixel connection pattern 1930 of the second pixel circuit PC2 through a 10^{th}-2 contact hole CNT10b. In the third pixel circuit PC3, the 2^{nd}-3 pixel connection pattern 2000c may be connected (e.g., electrically or physically connected) to the first pixel connection pattern 1930 of the third pixel circuit PC3 through a 10^{th}-3 contact hole CNT10c. The 10^{th}-1 contact hole CNT10a, the 10^{th}-2 contact hole CNT10b, and the 10^{th}-3 contact hole CNT10c may be arranged along the second direction (e.g., the x direction).

The second pixel connection pattern 2000 may include a conductive material, for example, Al, Pt, Pd, Ag, Mg, Au, Ni, Nd, Ir, Cr, Li, Ca, Mo, Ti, W, and/or Cu, and may be a layer or layers including the aforementioned material.

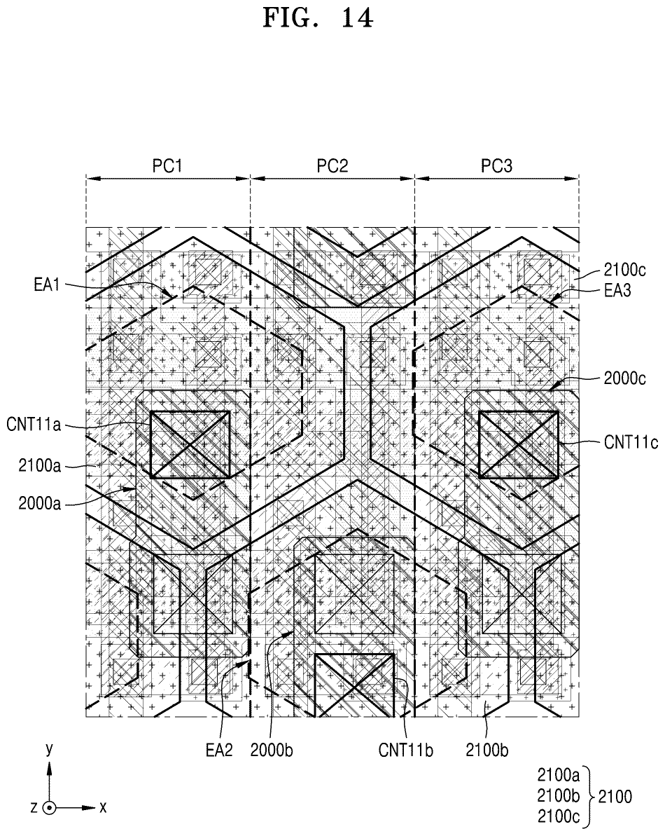

Referring to FIGS. 13 and 14, a third via insulating layer (111, see FIG. 15) may be disposed on the second pixel connection pattern 2000, and a pixel electrode 2100 may be disposed on the third via insulating layer (111, see FIG. 15).

The pixel electrode 2100 may include a first pixel electrode 2100a electrically connected to the first pixel circuit PC1, a second pixel electrode 2100b electrically connected to the second pixel circuit PC2, and a third pixel electrode 2100c electrically connected to the third pixel circuit PC3.

In the first pixel circuit PC1 to the third pixel circuit PC3, the first pixel electrode 2100a to the third pixel electrode 2100c may be electrically connected to the first semiconductor pattern (1100, see FIG. 4) and the second semiconductor pattern (1500, see FIG. 8) through the fourth connection pattern (1750, see FIG. 10), the first pixel connection pattern (1930, see FIG. 12), and the second pixel connection pattern (2000, see FIG. 13), respectively. For example, the first pixel electrode 2100a may be electrically connected to the semiconductor layer A1 of the first transistor (T1, see FIG. 5) of the first pixel circuit PC1 and the semiconductor layer A3 of the third transistor (T3, see FIG. 9) of the first pixel circuit PC1, the second pixel electrode 2100b may be electrically connected to the semiconductor layer A1 of the first transistor (T1, see FIG. 5) of the second pixel circuit PC2 and the semiconductor layer A3 of the third transistor (T3, see FIG. 9) of the second pixel circuit PC2, and the third pixel electrode 2100c may be electrically connected to the semiconductor layer A1 of the first transistor (T1, see FIG. 5) of the third pixel circuit PC3 and the semiconductor layer A3 of the third transistor (T3, see FIG. 9) of the third pixel circuit PC3.

The first pixel electrode 2100a may be connected (e.g., electrically or physically connected) to the 2^{nd}-1 pixel connection pattern 2000a through a 11^{th}-1 contact hole CNT11a. The second pixel electrode 2100b may be connected (e.g., electrically or physically connected) to the 2^{nd}-2 pixel connection pattern 2000b through a 11^{th}-2 contact hole CNT11b. The third pixel electrode 2100c may be connected (e.g., electrically or physically connected) to the 2^{nd}-3 pixel connection pattern 2000c through a 11^{th}-3 contact hole CNT11c.

In an embodiment, the 11^{th}-1 contact hole CNT11a, the 11^{th}-2 contact hole CNT11b, and the 11^{th}-3 contact hole CNT11c may overlap the first emission area EA1, the second emission area EA2, and the third emission area EA3, respectively. In another embodiment, the 11^{th}-1 contact hole CNT11a, the 11^{th}-2 contact hole CNT11b, and the 11^{th}-3 contact hole CNT11c may not overlap the first emission area EA1, the second emission area EA2, and the third emission area EA3, respectively.

In an embodiment, the first pixel electrode 2100a to the third pixel electrode 2100c may each have a hexagonal shape in a plan view. However, this is only an example. The shapes of the first pixel electrode 2100a to the third pixel electrode 2100c are not limited thereto and may be variously changed to, for example, polygons such as, for example, rectangles or circles. In an embodiment, a virtual line connecting the central portions of the first pixel electrode 2100a to the third pixel electrode 2100c may form a triangle.

A pixel-defining layer (130, see FIG. 15) described herein may be disposed on the pixel electrode 2100. A portion of an upper surface of each pixel electrode 2100 may be exposed through an opening in the pixel-defining layer (130, see FIG. 15), and an area defined by the opening in the pixel-defining layer (130, see FIG. 15) may be referred to as an emission area (EA, see FIG. 15) of each light-emitting element (LED, see FIG. 15). FIG. 14 illustrates the first emission area EA1 of the first light-emitting element including the first pixel electrode 2100a, the second emission area EA2 of the second light-emitting element including the second pixel electrode 2100b, and the third emission area EA3 of the third light-emitting element including the third pixel electrode 2100c. In an embodiment, the first emission area EA1, the second emission area EA2, and the third emission area EA3 may each have a hexagonal shape in a plan view. However, this is an example. The shapes of the first emission area EA1, the second emission area EA2, and the third emission area EA3 are not limited thereto and may be variously changed to polygons, such as, for example, rectangles, or circles.

FIG. 15 is a schematic cross-sectional view of a portion of the display panel 10, according to an embodiment.

Referring to FIG. 15, the pixel circuit (PC, see FIG. 2) including the first transistor T1, the second transistor T2, the third transistor T3, the first capacitor Cst, and the second capacitor Cpr may be disposed on the substrate 100, and the light-emitting element LED may be disposed on the pixel circuit (PC, see FIG. 2).

The substrate 100 may include a glass material, a ceramic material, a metal material, plastic, or a flexible or bendable material. In an example in which the substrate 100 is flexible or bendable, the substrate 100 may include polymer resin, such as, for example, polyethersulfone (PES), polyacrylate, polyetherimide (PEI), polyethyelenene napthalate (PEN), polyethylene terephthalate (PET), polyphenylene sulfide (PPS), polyarylate, polyimide (PI), polycarbonate, and cellulose acetate propionate (CAP).

The substrate 100 may have a single-layer structure or a multilayered structure including the materials described herein with reference to the substrate 100, and when the substrate 100 has a multilayered structure, the substrate 100 may additionally include an inorganic layer. For example, the substrate 100 may include a first organic base layer, a first inorganic barrier layer, a second organic base layer, and a second inorganic barrier layer. The first organic base layer and the second organic base layer may each include polymer resin. The first inorganic barrier layer and the second inorganic barrier layer may each be a barrier layer preventing the penetration of external foreign materials and may each be a layer or layers including an inorganic insulating material such as, for example, silicon nitride and/or silicon oxide.

A buffer layer 101 may be disposed over the substrate 100. The buffer layer 101 may be an inorganic insulating layer including an inorganic insulating material such as, for example, silicon nitride and/or silicon oxide, and may have a single-layer structure or a multilayered structure including the materials described with reference to the buffer layer 101.

The first transistor T1 including the semiconductor layer A1 may be disposed on the buffer layer 101. With regard to this, FIG. 15 illustrates the semiconductor layer A1 of the first transistor T1 that corresponds to a portion of the first semiconductor pattern 1100. The semiconductor layer A1 of the first transistor T1 may include a channel area C1 and a source area S1 and a drain area D1 which are disposed on opposite sides of the channel area C1 and doped with impurities.

The first insulating layer 102 may be disposed on the first semiconductor pattern 1100, for example, the semiconductor layer A1 of the first transistor T1. The first insulating layer 102 may include, for example, an inorganic insulating material such as, for example, silicon oxide, silicon nitride, and/or silicon oxynitride and may have a single-layer structure or a multilayered structure including the materials described with reference to the first insulating layer 102.

The first conductive pattern 1200 may be disposed on the first insulating layer 102. The first conductive pattern 1200 may include the gate electrode G1 of the first transistor T1 and/or the first lower electrode CE1 of the first capacitor Cst. The gate electrode G1 of the first transistor T1 may perform the function of the first lower electrode CE1 of the first capacitor Cst, or the first lower electrode CE1 of the first capacitor Cst may perform the function of the gate electrode G1 of the first transistor T1. In other words, the gate electrode G1 of the first transistor T1 may be formed integrally with the first lower electrode CE1 of the first capacitor Cst.

The second insulating layer 103 may be disposed on the gate electrode G1 of the first transistor T1 and/or the first lower electrode CE1 of the first capacitor Cst. The second insulating layer 103 may include, for example, an inorganic insulating material such as, for example, silicon oxide, silicon nitride, and/or silicon oxynitride and may have a single-layer structure or a multilayered structure including the material described with reference to the second insulating layer 103.

The second conductive pattern 1300 may be disposed on the second insulating layer 103. The second conductive pattern 1300 may include the first upper electrode CE2 of the first capacitor Cst. In some embodiments, the first upper electrode CE2 may include the same material as the first lower electrode CE1. The first upper electrode CE2 may overlap the gate electrode G1 of the first transistor T1 and/or the first lower electrode CE1of the first capacitor Cst.

The third insulating layer 104 may be disposed on the first upper electrode CE2. The third insulating layer 104 may include, for example, an inorganic insulating material such as, for example, silicon oxide, silicon nitride, and/or silicon oxynitride and may have a single-layer structure or a multilayered structure including the material described with reference to the third insulating layer 104.

The lower gate electrode G2a of the second transistor T2 and the lower gate electrode G3a of the third transistor T3 may be disposed on the third insulating layer 104. The first conductive line 1410 may include the lower gate electrode G2a of the second transistor T2, and the second conductive line 1420 may include the lower gate electrode

G3a of the third transistor T3. The lower gate electrode G2a of the second transistor T2 may be disposed under the semiconductor layer A2 of the second transistor T2. The lower gate electrode G3a of the third transistor T3 may be disposed under the semiconductor layer A3 of the third transistor T3.

The fourth insulating layer 105 may be disposed on the lower gate electrode G2a of the second transistor T2 and the lower gate electrode G3a of the third transistor T3. The fourth insulating layer 105 may include, for example, an inorganic insulating material such as, for example, silicon oxide, silicon nitride, and/or silicon oxynitride and may have a single-layer structure or a multilayered structure including the material described with reference to the fourth insulating layer 105.

The second semiconductor pattern 1500 may be disposed on the fourth insulating layer 105. The second semiconductor pattern 1500 may include the semiconductor layer A2 of the second transistor T2 and the semiconductor layer A3 of the third transistor T3. The second semiconductor pattern 1500 may include an oxide semiconductor material, such as, for example, ITZO or IGZO.

The semiconductor layer A2 of the second transistor T2 may include a channel area C2 and a source area S2 and a drain area D2 which are disposed on opposite sides of the channel area C2 and are conductive areas. The semiconductor layer A3 of the third transistor T3 may include a channel area C3 and a source area S3 and a drain area D3 which are disposed on opposite sides of the channel area C3 and are conductive areas.

The semiconductor layer A2 of the second transistor T2 and the semiconductor layer A1 of the first transistor T1 may be at different levels. For example, the semiconductor layer A1 of the first transistor T1 may be disposed on the buffer layer 101, and the semiconductor layer A2 of the second transistor T2 may be disposed on the fourth insulating layer 105. In other words, the vertical distance from the substrate 100 to the semiconductor layer A2 of the second transistor T2 may be greater than the vertical distance from the substrate 100 to the semiconductor layer A1 of the first transistor T1.

The fifth insulating layer 106 may be disposed on the second semiconductor pattern 1500. The fifth insulating layer 106 may include, for example, an inorganic insulating material such as, for example, silicon oxide, silicon nitride, and/or silicon oxynitride and may have a single-layer structure or a multilayered structure including the material described with reference to the fifth insulating layer 106. FIG. 15 illustrates that the fifth insulating layer 106 covers the entire substrate 100, but one or more embodiments are not limited thereto. In another embodiment, the fifth insulating layer 106 may be disposed only between the semiconductor layer A2 and the upper gate electrode G2b of the second transistor T2 and between the semiconductor layer A3 and the upper gate electrode G3b of the third transistor T3.

The upper gate electrode G2b of the second transistor T2 and the upper gate electrode G3b of the third transistor T3 may be disposed on the fifth insulating layer 106. The third conductive line 1610 may include the upper gate electrode G2b of the second transistor T2, and the fourth conductive line 1620 may include the upper gate electrode G3b of the third transistor T3. The upper gate electrode G2b of the second transistor T2 may be disposed on the semiconductor layer A2 of the second transistor T2. The upper gate electrode G3b of the third transistor T3 may be disposed on the semiconductor layer A3 of the third transistor T3.

The sixth insulating layer 107 may be disposed on the upper gate electrode G2b of the second transistor T2 and the upper gate electrode G3b of the third transistor T3.

The sixth insulating layer 107 may include, for example, an inorganic insulating material such as, for example, silicon oxide, silicon nitride, and/or silicon oxynitride and may have a single-layer structure or a multilayered structure including the material described with reference to the sixth insulating layer 107.

The second connection pattern 1720, the fourth connection pattern 1750, and the second lower electrode CE3 of the second capacitor Cpr may be disposed on the sixth insulating layer 107.

The second connection pattern 1720 may be electrically connected to the second conductive pattern 1300 through the second contact hole CNT2 penetrating the insulating layers (e.g., the third insulating layer 104, the fourth insulating layer 105, the fifth insulating layer 106, and the sixth insulating layer 107).

The fourth connection pattern 1750 may be electrically connected to the first semiconductor pattern 1100 (e.g., the semiconductor layer A1 of the first transistor T1) through the 5^{th}-1 contact hole CNT5a penetrating the insulating layers (e.g., the first insulating layer 102, the second insulating layer 103, the third insulating layer 104, the fourth insulating layer 105, the fifth insulating layer 106, and the sixth insulating layer 107).

The fourth connection pattern 1750 may be electrically connected to the second semiconductor pattern 1500 (e.g., the semiconductor layer A3 of the third transistor T3) through the 5^{th}-2 contact hole CNT5b penetrating the insulating layers (e.g., the fifth insulating layer 106 and the sixth insulating layer 107).

The third conductive pattern 1740 may include the second lower electrode CE3 of the second capacitor Cpr. The second lower electrode CE3 of the second capacitor Cpr may be electrically connected to the second semiconductor pattern 1500 (e.g., the semiconductor layer A2 of the second transistor T2 and/or the semiconductor layer A3 of the third transistor T3) through the fourth contact hole CNT4 penetrating the insulating layers (e.g., the fifth insulating layer 106 and the sixth insulating layer 107). In a cross-sectional view, the fourth contact hole CNT4 may be disposed between the upper gate electrode G2b of the second transistor T2 and the upper gate electrode G3b of the third transistor T3.

The seventh insulating layer 108 may be disposed on the second connection pattern 1720, the fourth connection pattern 1750, and the second lower electrode CE3 of the second capacitor Cpr. The seventh insulating layer 108 may be an inorganic insulating layer including an inorganic insulating material such as, for example, silicon oxide, silicon nitride, and/or silicon oxynitride. Alternatively, the seventh insulating layer 108 may be an organic insulating layer including an organic insulating material such as, for example, acryl, benzocyclobutene (BCB), polyimide, or hexamethyldisiloxane (HMDSO).

The second upper electrode CE4 of the second capacitor Cpr may be disposed on the seventh insulating layer 108. The second upper electrode CE4 of the second capacitor Cpr may overlap the second lower electrode CE3. The fifth conductive line 1800 may include the second upper electrode CE4 of the second capacitor Cpr.

The first via insulating layer 109 may be disposed on the second upper electrode CE4 of the second capacitor Cpr. The first via insulating layer 109 may include an organic insulating material. For example, the first via insulating layer 109 may include photoresist, BCB, polyimide, HMDSO, polymethylmethacrylate (PMMA), polystyrene, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any blend thereof.

The seventh conductive line 1920 and the first pixel connection pattern 1930 may be disposed on the first via insulating layer 109. The seventh conductive line 1920 may be an initialization voltage line (VIL, see FIG. 2) configured to transmit the initialization voltage (Vint, see FIG. 2). The seventh conductive line 1920 may be electrically connected to the second connection pattern 1720 through the seventh contact hole CNT7 penetrating the insulating layers (e.g., the seventh insulating layer 108 and the first via insulating layer 109). The seventh conductive line 1920 may be electrically connected to the second conductive pattern 1300 through the second connection pattern 1720. The second contact hole CNT2 may overlap the seventh contact hole CNT7.

The first pixel connection pattern 1930 may be electrically connected to the fourth connection pattern 1750 through the eighth contact hole CNT8 penetrating the insulating layers (e.g., the seventh insulating layer 108 and the first via insulating layer 109). The first pixel connection pattern 1930 may be electrically connected to the first semiconductor pattern 1100 and the second semiconductor pattern 1500 through the fourth connection pattern 1750.

The second via insulating layer 110 may be disposed on the seventh conductive line 1920 and the first pixel connection pattern 1930. The second via insulating layer 110 may include an organic insulating material. For example, the second via insulating layer 110 may include photoresist, BCB, polyimide, HMDSO, PMMA, polystyrene, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any blend thereof.

The second pixel connection pattern 2000 may be disposed on the second via insulating layer 110. The second pixel connection pattern 2000 may be electrically connected to the first pixel connection pattern 1930 through a contact hole penetrating the second via insulating layer 110. The second pixel connection pattern 2000 may be electrically connected to the first semiconductor pattern 1100 and the second semiconductor pattern 1500 through the first pixel connection pattern 1930 and the fourth connection pattern 1750.

The third via insulating layer 111 may be disposed on the second pixel connection pattern 2000. The third via insulating layer 111 may include an organic insulating material. For example, the third via insulating layer 111 may include photoresist, BCB, polyimide, HMDSO, PMMA, polystyrene, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any blend thereof.

The light-emitting element LED may be disposed on the third via insulating layer 111. The light-emitting element LED may include the pixel electrode 2100, an intermediate layer 2200, and an opposite electrode 2300.

The pixel electrode 2100 may be a (semi-)light-transmissive electrode or a

reflection electrode. For example, the pixel electrode 2100 may include a reflection layer including Ag, Mg, Al, Pt, Pd, Au, Ni, Nd, Ir, Cr, or a combination thereof, and a transparent or translucent electrode layer formed on the reflection layer. The transparent or translucent electrode layer may include at least one material selected from the group consisting of indium tin oxide (ITO), indium zinc oxide (IZO), zinc oxide (ZnO), indium oxide (In203), indium gallium oxide (IGO), and aluminum zinc oxide (AZO). For example, the pixel electrode 2100 may have a tri-layer structure of ITO/Ag/ITO.

Edges of the pixel electrode 2100 may be covered by the pixel-defining layer 130, and an inner portion of the pixel electrode 2100 may overlap the intermediate layer 2200 through a pixel opening 130OP of the pixel-defining layer 130. That is, the pixel-defining layer 130 may cover the edges of the pixel electrode 2100 and define the pixel opening 130OP exposing a portion of the pixel electrode 2100. The pixel opening 130OP of the pixel-defining layer 130 may define the emission area EA of the light-emitting element LED.

While the pixel electrode 2100 is formed for each light-emitting element LED, the opposite electrode 2300 may be formed to correspond to a plurality of light-emitting elements LED. In other words, the light-emitting elements LED may share the opposite electrode 2300, and a stack structure including the pixel electrode 2100, the intermediate layer 2200, and the opposite electrode 2300 may correspond to the light-emitting element LED.

The intermediate layer 2200 may be disposed on the pixel electrode 2100. The intermediate layer 2200 may include an emission layer, a lower functional layer under the emission layer, and an upper functional layer above the emission layer. The emission layer may be patterned corresponding to the pixel electrode 2100. For example, a first emission layer may be patterned corresponding to a first pixel electrode (2100a, see FIG. 14), a second emission layer may be patterned corresponding to a second pixel electrode (2100b, see FIG. 14), and a third emission layer may be patterned corresponding to a third pixel electrode (2100c, see FIG. 14). Each of the first emission layer, the second emission layer, and the third emission layer may include a high-molecular-weight organic material or a low-molecular-weight organic material emitting light of a certain color. The lower functional layer may be a hole transport layer (HTL). Alternatively, the lower functional layer may include a hole injection layer (HIL) and the HTL. The upper functional layer may include an electron transport layer (ETL) and/or an electron injection layer (EIL). The lower functional layer and the upper functional layer may be integrally formed to correspond to the light-emitting elements LED. In another embodiment, the lower functional layer or the upper functional layer may be omitted.

The opposite electrode 2300 may be disposed on the intermediate layer 2200. The opposite electrode 2300 may be a transmissive electrode, a semi-transmissive electrode, or a reflection electrode. The opposite electrode 2300 may include, for example, Li, Ag, Mg, Al, Al-Li, Ca, Mg-In, Mg-Ag, ytterbium (Yb), Ag-Yb, ITO, IZO, or an arbitrary combination thereof. The opposite electrode 2300 may be integrally formed to correspond to the light-emitting elements LED.

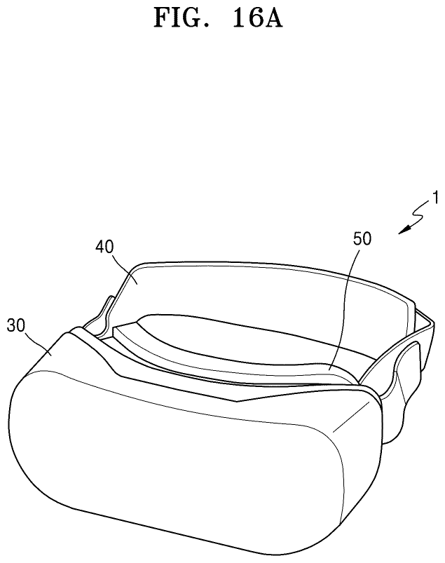

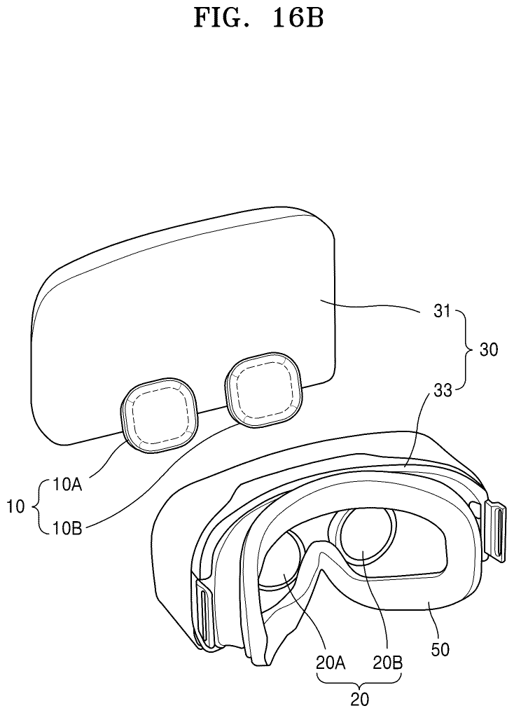

FIG. 16A is a schematic perspective view of an electronic device 1 according to an embodiment. FIG. 16B is a schematic exploded view of the electronic device 1 according to an embodiment. The electronic device 1 of FIGS. 16A and 16B may include the display panel 10 described with reference to FIGS. 1 to 15.

Referring to FIGS. 16A and 16B, the electronic device 1 may be mounted on the head of the user (not illustrated). The electronic device 1 may provide images while the actual peripheral visual field of the user is blocked or is not blocked. The user wearing the electronic device 1 may be easily immersed in augmented reality or virtual reality. The electronic device 1 may include the display panel 10, an optical unit 20, a case unit 30, a fixing portion 40, and a cushion portion 50.

The display panel 10 may provide images. The display panel 10 may emit light in association with providing images. The display panel 10 may be accommodated in the case unit 30. In an embodiment, the electronic device 1 may include a plurality of display panels 10. For example, the electronic device 1 may include a first display panel 10A and a second display panel 10B. In this case, the first display panel 10A and the second display panel 10B may overlap the plurality of optical units 20. The first display panel 10A may be a left-eye display panel. The second display panel 10B may be a right-eye display panel. In another embodiment, the electronic device 1 may include one display panel 10. In this case, each of the optical units 20 may overlap one display panel 10.

The optical unit 20 may transmit light emitted from the display panel 10. The optical unit 20 may refract and/or reflect the light emitted from the display panel 10. In an embodiment, the optical unit 20 may magnify an image provided from the display panel 10. The optical unit 20 may be disposed to face the display panel 10. In an example in which the user wears the electronic device 1, the optical unit 20 may be disposed between the user and the display panel 10. Therefore, the user may recognize the light emitted from the display panel 10 and refracted and/or reflected by the optical unit 20. In an embodiment, the optical unit 20 may include at least one of a lens and a mirror.

In an embodiment, the electronic device 1 may include a plurality of optical units 20. For example, the electronic device 1 may include a first optical unit 20A and a second optical unit 20B. In this case, the first display panel 10A may face the first optical unit 20A.

The second display panel 10B may face the second optical unit 20B. The first optical unit 20A may be a left-eye optical unit. The second optical unit 20B may be a right-eye optical unit. In another embodiment, the electronic device 1 may include one optical unit 20.

The case unit 30 may accommodate the display panel 10 and the optical unit 20. The case unit 30 may have a space therein, and the display panel 10 and the optical unit 20 may be placed in the space. The case unit 30 may protect the display panel 10 and the optical unit 20 from external impact. In an embodiment, the case unit 30 may be divided into a cover portion 31 and a body portion 33. In another embodiment, the cover portion 31 may be formed integrally with the body portion 33. In an embodiment, the cover portion 31 may be opaque. In an embodiment, the cover portion 31 may be transparent.

The case unit 30 may support the display panel 10 that is curved. For example, the display panel 10 may be fixed into the case unit 30. In some aspects, the case unit 30 may support the curved display panel 10 in association with maintaining the shape of the curved display panel 10.

The fixing portion 40 may fix the case unit 30 to the user's head. Therefore, the electronic device 1 may be placed on the user's head. In an embodiment, the length of the fixing portion 40 may be adjusted. For example, the length of the fixing portion 40 may be adjusted according to the head circumference of the user.

The fixing portion 40 may attach the electronic device 1 to the user's head. In an embodiment, the fixing portion 40 may have elasticity. FIG. 16A illustrates that the fixing portion 40 is a strap, but in another embodiment, the fixing portion 40 may be in various forms such as, for example, a helmet coupled to the case unit 30 and a spectacle temple coupled to the case unit 30. The fixing portion 40 may be connected to the case unit 30. In an embodiment, the fixing portion 40 may be detachable from the case unit 30.

The cushion portion 50 may improve the wearing comfort of the user. In an example in which the user wears the electronic device 1, the cushion portion 50 may be disposed between the user and the case unit 30. In an embodiment, the cushion portion 50 may be attached to the case unit 30. In an embodiment, the cushion portion 50 may be detachable from the case unit 30. In an embodiment, the cushion portion 50 may be omitted.

The cushion portion 50 may include a material whose shape is freely changeable. For example, the cushion portion 50 may include polymer resin. For example, the cushion portion 50 may include at least one of polyurethane, polycarbonate, polypropylene, and polyethylene. In another embodiment, the cushion portion 50 may include a sponge formed by foam-molding a rubber liquid, a urethane-based material, and an acryl-based material.

According to the one or more embodiments, a display panel with improved display quality and resolution may be provided. The above effect is an example, and the scope of the disclosure is not limited thereto.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate;
a first semiconductor pattern disposed on the substrate and extending in a first direction;
a first conductive pattern disposed on the first semiconductor pattern and comprising a portion overlapping the first semiconductor pattern;
a second conductive pattern disposed on the first conductive pattern and comprising:
a line portion extending in a second direction, the second direction being perpendicular to the first direction, and
branch portions extending from the line portion in the first direction and each overlapping the first semiconductor pattern and the first conductive pattern;
a first conductive line and a second conductive line respectively disposed on the second conductive pattern and extending in the second direction;
a second semiconductor pattern disposed on the first conductive line and the second conductive line and extending in the first direction;
a third conductive line disposed on the second semiconductor pattern, extending in the second direction, and overlapping the first conductive line;
a fourth conductive line disposed on the second semiconductor pattern, extending in the second direction, and overlapping the second conductive line;
a third conductive pattern disposed on the third conductive line and the fourth conductive line and comprising:
a first portion overlapping the third conductive line,
a second portion overlapping the fourth conductive line, and
a third portion located between the first portion and the second portion;
a fifth conductive line disposed on the third conductive pattern, extending in the first direction, and comprising a portion overlapping the third conductive pattern;
a sixth conductive line disposed on the fifth conductive line, extending in the second direction, and electrically connected to the first semiconductor pattern; and
a seventh conductive line disposed on the fifth conductive line, extending in the second direction, overlapping the line portion of the second conductive pattern, and electrically connected to the second conductive pattern.

2. The display panel of claim 1, further comprising a first connection pattern disposed on a same layer as the third conductive pattern, located between the first semiconductor pattern and the sixth conductive line, and electrically connected to the first semiconductor pattern through a first contact hole.

3. The display panel of claim 2, wherein:
the sixth conductive line is electrically connected to the first connection pattern through a second contact hole, and
the first contact hole overlaps the second contact hole.

4. The display panel of claim 2, further comprising a second connection pattern disposed on a same layer as the third conductive pattern, located between the second conductive pattern and the seventh conductive line, and electrically connected to the second conductive pattern through a third contact hole.

5. The display panel of claim 4, wherein:
the seventh conductive line is electrically connected to the second connection pattern through a fourth contact hole, and
the third contact hole overlaps the fourth contact hole.

6. The display panel of claim 4, wherein the first connection pattern is arranged adjacent to the second connection pattern along the first direction.

7. The display panel of claim 4, further comprising a third connection pattern disposed on a same layer as the third conductive pattern and electrically connected to the first conductive pattern through a fifth contact hole,
wherein the fifth contact hole and the first contact hole are arranged along the second direction.

8. The display panel of claim 7, wherein:
the third connection pattern is electrically connected to the second semiconductor pattern through a sixth contact hole, and
the fifth contact hole and the sixth contact hole are arranged along the first direction.

9. The display panel of claim 1, wherein, in a plan view, the first semiconductor pattern is arranged in parallel with the second semiconductor pattern.

10. The display panel of claim 1, wherein:
the first semiconductor pattern comprises a silicon semiconductor material, and
the second semiconductor pattern comprises an oxide semiconductor material.

11. A display panel comprising:
a first pixel circuit, a second pixel circuit, and a third pixel circuit arranged adjacent to each other in a first direction and each comprising a first transistor, a second transistor, a third transistor, a first capacitor, and a second capacitor that are disposed on a substrate;
a first light-emitting element, a second light-emitting element, and a third light-emitting element electrically connected to the first pixel circuit, the second pixel circuit, and the third pixel circuit, respectively, and emitting light of different respective colors;
a first conductive pattern comprising a line portion and branch portions, wherein:
the line portion is disposed on a gate electrode of the first transistor, disposed under a semiconductor layer of the second transistor, and extends in the first direction, and
the branch portions respectively extend from the line portion in a second direction perpendicular to the first direction;
a first gate line disposed on the semiconductor layer of the second transistor, extending in the first direction, and configured to transmit a first gate signal to a gate electrode of the second transistor;
a second gate line disposed on a same layer as the first gate line, extending in the first direction, and configured to transmit a second gate signal to a gate electrode of the third transistor;
a second conductive pattern disposed on the first gate line, comprising a first portion overlapping the first gate line, a second portion overlapping the second gate line, and a third portion located between the first portion and the second portion, and electrically connected to each of the semiconductor layer of the second transistor and a semiconductor layer of the third transistor;
a data line disposed on the second conductive pattern, extending in the second direction, comprising a first portion overlapping the second conductive pattern, and configured to transmit a data signal;
a driving voltage line disposed on the data line, extending in the first direction, and electrically connected to a semiconductor layer of the first transistor; and
an initialization voltage line disposed on a same layer as the driving voltage line, extending in the first direction, overlapping the line portion of the first conductive pattern, and electrically connected to the first conductive pattern.

12. The display panel of claim 11, wherein each of the semiconductor layer of the first transistor and the semiconductor layer of the second transistor extends in the second direction.

13. The display panel of claim 12, wherein:
the semiconductor layer of the first transistor comprises a silicon semiconductor material, and
the semiconductor layer of the second transistor comprises an oxide semiconductor material.

14. The display panel of claim 11, wherein the second capacitor comprises the second conductive pattern and the first portion of the data line.

15. The display panel of claim 14, wherein:
the data line further comprises a second portion and a third portion spaced apart from each other with the first portion of the data line between the second portion and the third portion, and each of the second portion and the third portion extends in the second direction, and
a maximum width of the first portion of the data line in the first direction is greater than each of a maximum width of the second portion of the data line in the first direction and a maximum width of the third portion of the data line in the first direction.

16. The display panel of claim 11, further comprising:
a first connection pattern disposed on a same layer as the second conductive pattern and electrically connecting the driving voltage line to the semiconductor layer of the first transistor; and
a second connection pattern disposed on a same layer as the second conductive pattern and electrically connecting the first conductive pattern to the initialization voltage line,
wherein the first connection pattern is arranged adjacent to the second connection pattern along the second direction.

17. The display panel of claim 16, further comprising a third connection pattern disposed on a same layer as the second conductive pattern and electrically connecting the gate electrode of the first transistor to the semiconductor layer of the second transistor.

18. The display panel of claim 17, wherein:
the first connection pattern is electrically connected to the semiconductor layer of the first transistor through a first contact hole,
the second connection pattern is electrically connected to the first conductive pattern through a second contact hole,
the third connection pattern is electrically connected to the gate electrode of the first transistor through a third contact hole and is electrically connected to the semiconductor layer of the second transistor through a fourth contact hole,
the first contact hole and the third contact hole are arranged along the first direction, and
the third contact hole and the fourth contact hole are arranged along the second direction.

19. The display panel of claim 18, wherein:
the driving voltage line is electrically connected to the first connection pattern through a fifth contact hole, and
the fifth contact hole overlaps the first contact hole.

20. An electronic device comprising:
a display panel comprising:
a substrate;
a first semiconductor pattern disposed on the substrate and extending in a first direction;
a first conductive pattern disposed on the first semiconductor pattern and comprising a portion overlapping the first semiconductor pattern;
a second conductive pattern disposed on the first conductive pattern and comprising:
a line portion extending in a second direction, the second direction being perpendicular to the first direction, and
branch portions extending from the line portion in the first direction and each overlapping the first semiconductor pattern and the first conductive pattern;
a first conductive line and a second conductive line respectively disposed on the second conductive pattern and extending in the second direction;
a second semiconductor pattern disposed on the first conductive line and the second conductive line and extending in the first direction;
a third conductive line disposed on the second semiconductor pattern, extending in the second direction, and overlapping the first conductive line;
a fourth conductive line disposed on the second semiconductor pattern, extending in the second direction, and overlapping the second conductive line;
a third conductive pattern disposed on the third conductive line and the fourth conductive line and comprising:
a first portion overlapping the third conductive line,
a second portion overlapping the fourth conductive line, and
a third portion located between the first portion and the second portion;
a fifth conductive line disposed on the third conductive pattern, extending in the first direction, and comprising a portion overlapping the third conductive pattern;
a sixth conductive line disposed on the fifth conductive line, extending in the second direction, and electrically connected to the first semiconductor pattern; and
a seventh conductive line disposed on the fifth conductive line, extending in the second direction, overlapping the line portion of the second conductive pattern, and electrically connected to the second conductive pattern.
